(19) United States
(12) Patent Application Publication
(10) Pub. No.: US 2025/0270446 A1
(43) Pub. Date: Aug. 28, 2025

(54) COMPOSITION, METHOD OF TREATING METAL-CONTAINING FILM BY USING THE SAME, AND METHOD OF PREPARING SEMICONDUCTOR DEVICE BY USING THE COMPOSITION

(71) Applicant: Samsung Electronics Co., Ltd., Suwon-si (KR)

(72) Inventors: Insun PARK, Suwon-si (KR); Byungjoon KANG, Suwon-si (KR); Sangwan KIM, Suwon-si (KR); Sungmin KIM, Suwon-si (KR); Jina KIM, Suwon-si (KR); Gayoung SONG, Suwon-si (KR); Jungmin OH, Suwon-si (KR); Kum Hee LEE, Suwon-si (KR); Cheol HAM, Suwon-si (KR); Kyuyoung HWANG, Suwon-si (KR)

(73) Assignee: Samsung Electronics Co., Ltd., Suwon-si (KR)

(21) Appl. No.: 19/018,616

(22) Filed: Jan. 13, 2025

(30) Foreign Application Priority Data
Feb. 27, 2024 (KR) 10-2024-0028157

(51) Int. Cl. C09K 13/06; H01L 21/3105; H01L 21/311; H01L 21/321; H01L 21/3213

(52) U.S. Cl. CPC C09K 13/06; H01L 21/31053; H01L 21/31111; H01L 21/3212; H01L 21/32134

(57) ABSTRACT

Provided are a composition, a method of treating a metal-containing film by using the same, and a method of manufacturing a semiconductor device by using the composition, the composition including an oxidizing agent, an acid, and a selective etching inhibitor, wherein the selective etching inhibitor includes an ammonium compound and a polymer having a nitrogen-containing repeating unit.

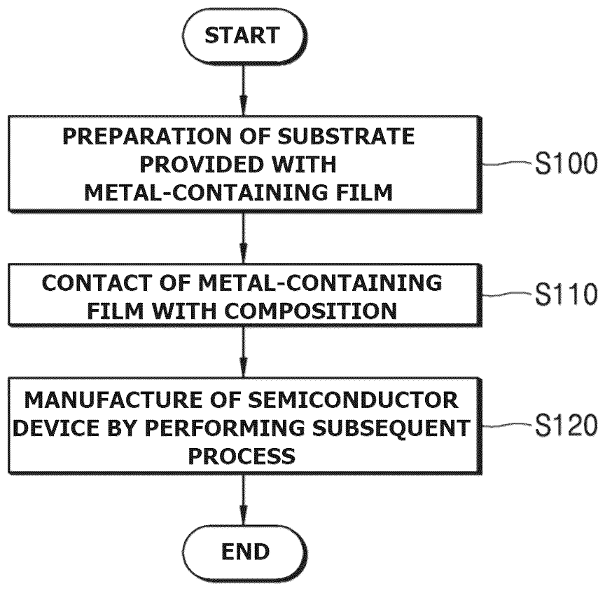

### CROSS-REFERENCE TO RELATED APPLICATION

This application is based on and claims priority under 35 U.S.C. § 119 to Korean Patent Application No. 10-2024-0028157, filed on Feb. 27, 2024, in the Korean Intellectual Property Office, the disclosure of which is incorporated by reference herein in its entirety.

### BACKGROUND

### 1. Field

The disclosure relates to a composition, a method of treating a metal-containing film using the same, and a method of manufacturing a semiconductor device using the composition.

### 2. Description of the Related Art

To satisfy the demands of consumers for semiconductor devices with excellent performance and low prices, there is a need for an increase in the degree of integration and an improvement in reliability of semiconductor devices. As the degree of integration of semiconductor devices increases, damage to components of semiconductor devices during a manufacturing process has a greater effect on the reliability and electrical characteristics of semiconductor devices. In particular, in the process of manufacturing a semiconductor device, various processing processes, such as etching, cleaning, and polishing, may be performed on an included film (e.g., a metal-containing film). In this regard, to perform an effective treatment process on a metal-containing film, there is a continuing need for a composition having an appropriate etching rate or the like.

### SUMMARY

Provided are a composition capable of effectively controlling an etching rate for various metal-containing films, a method of treating a metal-containing film by using the composition, and a method of manufacturing a semiconductor device by using the composition.

Additional aspects will be set forth in part in the description which follows and, in part, will be apparent from the description, or may be learned by practice of the presented embodiments of the disclosure.

According to an aspect of the disclosure a composition includes an oxidizing agent, an acid, and a selective etching inhibitor, wherein the selective etching inhibitor includes an ammonium compound (e.g., ammonium salt) and a polymer having a nitrogen-containing repeating unit.

The oxidizing agent may include hydrogen peroxide.

The acid may include phosphoric acid.

The nitrogen-containing repeating unit may include at least one of a repeating unit represented by Formula 1-1, a repeating unit represented by Formula 1-2, a repeating unit represented by Formula 1-3, a repeating unit represented by Formula 1-4, or a combination thereof:

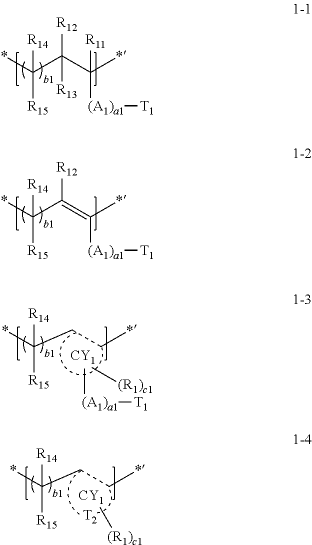

wherein A₁ in Formulae 1-1 to 1-3 may be at least one of *—C(R₁₆)(R₁₇)—*′, *—N(R₁₆)—*′, *—C(═O)—*′, *—O—*′, or *—S—*′,
a1 in Formulae 1-1 to 1-3 may be an integer from 0 to 20, and when a1 is 2 or more, two or more of A₁ may be identical to or different from each other,
b1 in Formulae 1-1 to 1-4 may be an integer from 0 to 10, and when b1 is 2 or more, at least two of *—C(R₁₄)(R₁₅)—*′ may be identical to or different from each other,
T₁ in Formulae 1-1 to 1-3 may be at least one of *—N(Z₁₁)(Z₁₂), *—[N(Z₁₁)(Z₁₂)(Z₁₃)]⁺[Z₁₄]⁻, a group represented by Formula AN, or a group represented by Formula BN,

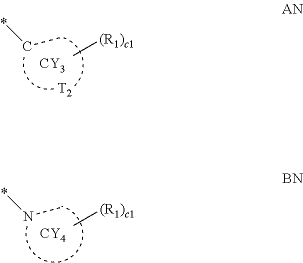

ring CY₁ to ring CY₄ in Formulae 1-3, 1-4, AN, and BN may each independently be a C₂-C₁₀ cyclic group,
c1 in Formulae 1-3, 1-4, AN, and BN may be an integer from 0 to 10, and when c1 is 2 or more, two or more of R₁ may be identical to or different from each other,
T₂ in Formulae 1-4 and AN may be *—N(Z₁₁)—*′ or *—[N(Z₁₁)(Z₁₂)]⁺[Z₁₄]⁻—*′,
R₁, R₁₁, R₁₂, R₁₃, R₁₄, R₁₅, R₁₆, R₁₇, Z₁₁, Z₁₂, and Z₁₃ may each independently be
hydrogen, deuterium, *—F, *—Cl, *—Br, *—I, *—OH, *—SH, *—C(═O)-Q₁, *—NH—C(═O)-Q₁, *—C(═O)—O-Q₁, *—SO₂-Q₁, *—P(═O)-(Q₁)(Q₂), *—N(Q₁)(Q₂), *—[N(Q₁)(Q₂)(Q₃)]⁺[Q₄]-, or *—(O—CH₂CH₂)ₙ₁—OH, or
a C₁-C₃₀ alkyl group, a C₁-C₃₀ alkoxy group, a C₂-C₃₀ alkenyl group, a C₃-C₃₀ carbocyclic group, or a C₁-C₃₀ heterocyclic group, each unsubstituted or substituted with deuterium, *—F, *—Cl, *—Br, *—I, *—OH, *—SH, *—C(═O)-Q₁₁, *—NH—C(═O)-Q₁₁, *—C(═O)—O-Q₁₁, *—SO₂-Q₁₁, *—P(═O)-(Q₁₁)(Q₁₂), *—N(Q₁₁)(Q₁₂), *—[N(Q₁₁)(Q₁₂)(Q₁₃)]⁺[Q₁₄]⁻, *—(O—CH₂CH₂)ₙ₂—OH, a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or a combination thereof,
n1 and n2 may each independently be an integer from 1 to 20,
two or more of R₁, R₁₁, R₁₂, R₁₃, R₁₄, R₁₅, R₁₆, R₁₇, Z₁₁, Z₁₂, and Z₁₃ may optionally be bonded together to form a cyclic group having 2 to 10 carbon atoms,
Q₁ to Q₃ and Qu to Q₁₃ may each independently be
hydrogen, deuterium, *—F, *—Cl, *—Br, *—I, *—OH, *—SH, *—C(═O)—H, *—C(═O)—OH, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), or *—N(CH₃)₂, or
a C₁-C₃₀ alkyl group, a C₁-C₃₀ alkoxy group, a C₂-C₃₀ alkenyl group, a C₃-C₃₀ carbocyclic group, or a C₁-C₃₀ heterocyclic group, each unsubstituted or substituted with deuterium, *—F, *—Cl, *—Br, *—I, *—OH, *—SH, *—C(═O)—H, *—C(═O)—OH, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), *—N(CH₃)₂, a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or a combination thereof,
[Z₁₄]⁻, [Q₄]⁻, and [Q₁₄]⁻ may each be an anion, and
* and *′ each indicate a binding site to a neighboring atom.

The ammonium compound may include a cation represented by [N(X₁)(X₂)(X₃)(X₄)]⁺, wherein X₁ to X₄ may each independently be hydrogen or a C₁-C₂₀ alkyl group.

The ammonium compound may include an anion, wherein
the anion may include at least one of F⁻, Cl⁻, Br⁻, I⁻, [OH]⁻, [(R₁₀) CO₂]⁻, [CO₃]²⁻, [NO₃]⁻, [SO₄]²⁻, [(R₁₀)SO₄]⁻, [(R₁₀)SO₃]⁻, [C₆H₇O₇]⁻, [C₆H₆O₇]²⁻, [C₆H₅O₇]³⁻, [PO₃]³⁻, [SO₃]²⁻, [C₂O₄]²⁻, [C₄H₄O₆]²⁻, [C₅H₈NO₄]⁻, [C₇H₅O₃]⁻, [BF₄]⁻, or a combination thereof, wherein
R₁₀ may be one of
hydrogen, deuterium, *—OH, *—SH, or *—NH₂, or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with deuterium, *—F, *—Cl, *—Br, *—I, *—OH, *—SH, *—NH₂, *—C(═O)—OH, a C₁-C₂₀ alkyl group, a C₁-C₂₀ alkoxy group, or any combination thereof.

According to another aspect of the disclosure, a method of treating a metal-containing film includes preparing a substrate provided with a metal-containing film, and contacting the metal-containing film with the composition.

A metal included in the metal-containing film may include titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), copper (Cu), or any combination thereof.

The metal-containing film may include a metal, metal nitride, metal oxide, metal oxynitride, or a combination thereof.

By the contacting of the metal-containing film with the composition, at least a portion of the metal-containing film may be etched, cleaned, or polished.

According to another aspect of the disclosure, a method of manufacturing a semiconductor device includes preparing a substrate provided with a metal-containing film, contacting the metal-containing film with the composition, and preparing a semiconductor device by performing at least one subsequent manufacturing process.

### BRIEF DESCRIPTION OF THE DRAWINGS

The above and other aspects, features, and advantages of certain embodiments of the disclosure will be more apparent from the following description taken in conjunction with the FIGURE which shows a flowchart explaining a process of manufacturing a semiconductor device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the FIGURE, to explain aspects. As used herein, the term “and/or” includes any and all combinations of one or more of the associated listed items. Expressions such as “at least one of,” when preceding a list of elements, modify the entire list of elements and do not modify the individual elements of the list.

Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, whenever a range of values is enumerated, the range includes all values within the range as if recorded explicitly clearly, and may further include the boundaries of the range. Accordingly, the range of “X” to “Y” includes all values between X and Y, including X and Y.

Herein, a C₂-C₁₀ cyclic group may be a C₃-C₁₀ carbocyclic group or a C₂-C₁₀ heterocyclic group.

Herein, a C₃-C₃₀ carbocyclic group may be a C₃-C₂₀ carbocyclic group, such as a C₃-C₁₀ carbocyclic group, such as a C₃-C₈ carbocyclic group, or a C₃-C₆ carbocyclic group. The carbocyclic group may be a cycloalkane group, a cycloalkene group, or an arene group.

Herein, C₁-C₃₀ heterocyclic group may be C₁-C₂₀ heterocyclic group, such as C₁-C₁₀ heterocyclic group, such as C₃-C₈ heterocyclic group, or such as C₃-C₆ heterocyclic group. The heterocyclic group may contain at least one hetero atom selected from N, O, S, P and B as a ring-forming atom. The heterocyclic group may be a heterocycloalkane group, a heterocycloalkene group, or a heteroarene group.

Herein, a C₁-C₃₀ alkyl group may be a C₁-C₂₀ alkyl group, such as a C₁-C₁₀ alkyl group, a C₂-C₈ alkyl group, or a C₃-C₆ alkyl group. A C₁-C₃₀ alkoxy group may be a C₁-C₂₀ alkoxy group, such as a C₁-C₁₀ alkoxy group, a C₂-C₈ alkoxy group, or a C₃-C₆ alkoxy group. A C₂-C₃₀ alkenyl group may be a C₂-C₂₀ alkenyl group, such as a C₂-C₁₀ alkenyl group, a C₂-C₈ alkenyl group, or a C₂-C₆ alkenyl group.

### Metal-Containing Film

A metal included in the metal-containing film may be an alkali metal (e.g., sodium (Na), potassium (K), rubidium (Rb), cesium (Cs), etc.), an alkaline earth metal (e.g., beryllium (Be), magnesium (Mg), calcium (Ca), strontium (Sr), barium (Ba), etc.), a lanthanide metal (e.g., lanthanum (La), europium (Eu), terbium (Tb), ytterbium (Yb), etc.), a transition metal (e.g., scandium (Sc), yttrium (Y), titanium (Ti), zirconium (Zr), hafnium (Hf), vanadium (V), niobium (Nb), tantalum (Ta), chromium (Cr), molybdenum (Mo), tungsten (W), manganese (Mn), iron (Fe), ruthenium (Ru), osmium (Os), cobalt (Co), rhodium (Rh), nickel (Ni), copper (Cu), silver (Ag), zinc (Zn), etc.), a post-transition metal (e.g., aluminum (Al), gallium (Ga), indium (In), thallium (Tl), tin (Sn), bismuth (Bi), etc.), or any combination thereof.

In one or more embodiments, the metal included in the metal-containing film may include Ti, In, Al, Co, La, Sc, Ga, W, Mo, Ru, Zn, Hf, Cu, or any combination thereof.

In one or more embodiments, the metal-containing film may include Al, Ti, La, W, or any combination thereof.

In one or more embodiments, the metal-containing film may include Ti and/or W.

The metal-containing film may include a metal, metal nitride, metal oxide, metal oxynitride, or any combination thereof.

In one or more embodiments, the metal-containing film may include metal nitride, metal oxide, metal oxynitride, or any combination thereof, and a metal included in each of the metal nitride, the metal oxide, and the metal oxynitride may include Ti, In, Al, Co, La, Sc, Ga, W, Mo, Ru, Zn, Hf, Cu, or any combination thereof.

In one or more embodiments, the metal-containing film may include the metal nitride. The metal included in the metal nitride may include In, Ti, Al, La, Sc, Ga, Zn, Hf, W, or any combination thereof.

In one or more embodiment, the metal-containing film may include titanium nitride. The titanium nitride may further include, for example, as a dopant, In, Al, La, Sc, Ga, Hf, Zn, W, or any combination thereof. In one or more embodiments, the metal-containing film may include titanium nitride (TiN), titanium nitride further including Al (e.g., titanium aluminum nitride (TiAlN)), titanium nitride further including La (e.g., TiLaN), and/or the like.

In one or more embodiments, the metal-containing film may include the metal oxide. The metal included in the metal oxide may include Ti, Al, La, Sc, Ga, Hf, or any combination thereof. In one or more embodiments, the metal-containing film may include aluminum oxide (e.g., Al₂O₃), indium gallium zinc oxide (IGZO), and/or the like.

In one or more embodiments, the metal-containing film may include the metal nitride and the metal oxide.

In one or more embodiments, the metal-containing film may further include, in addition to the aforementioned metal, a metalloid (e.g., boron (B), silicon (Si), germanium (Ge), arsenic (As), antimony (Sb), tellurium (Te), etc.), a non-metal (e.g., nitrogen (N), phosphorus (P), oxygen (O), sulfur(S), selenium (Se), etc.), or any combination thereof.

For example, the metal-containing film may further include silicon oxide.

The metal-containing film may have a single-layer structure including (or consisting of) at least one type of materials or a multi-layer structure or three-dimensional pattern structure including different materials from each other. For example, the metal-containing film may have i) a single-layer structure including (or consisting of) titanium nitride, ii) a double-layer structure or three-dimensional pattern structure including a first layer including (or consisting of) titanium nitride and a second layer including titanium nitride further including Al (e.g., TiAlN), iii) a double-layer structure or three-dimensional pattern structure including a first layer including (or consisting of) titanium nitride and a second layer including (or consisting of) aluminum oxide, and/or iv) a double-layer structure or three-dimensional pattern structure including a first layer including (or consisting of) titanium nitride and a second layer including (or consisting of) W.

### Composition

A composition may include an oxidizing agent, an acid, and a selective etching inhibitor.

The composition may be used in various treatment processes for processing the metal-containing film, such as etching, cleaning, polishing, etc.

The composition may further include a solvent, e.g., water.

In at least one embodiment, the composition may consist of at least one oxidizing agent, at least one acid, at least one selective etching inhibitor, and water or may consist of an oxidizing agent, an acid, a selective etching inhibitor, and water.

### Oxidizing Agent

The oxidizing agent may serve to etch at least a portion of the metal-containing film, and may include, for example, at least one of hydrogen peroxide, nitric acid, and/or ammonium sulfate.

In one or more embodiments, the oxidizing agent may include hydrogen peroxide.

In one or more embodiments, the oxidizing agent may be hydrogen peroxide.

The amount (e.g., weight) of the oxidizing agent may be, for example per 100 wt % of the composition, in a range of about 0.001 wt % to about 50 wt %, about 0.01 wt % to about 50 wt %, about 0.1 wt % to about 50 wt %, about 0.5 wt % to about 50 wt %, about 1 wt % to about 50 wt %, about 0.001 wt % to about 30 wt %, about 0.01 wt % to about 30 wt %, about 0.1 wt % to about 30 wt %, about 0.5 wt % to about 30 wt %, about 1 wt % to about 30 wt %, about 0.001 wt % to about 20 wt %, about 0.01 wt % to about 20 wt %, about 0.1 wt % to about 20 wt %, about 0.5 wt % to about 20 wt %, about 1 wt % to about 20 wt %, about 0.001 wt % to about 10 wt %, about 0.01 wt % to about 10 wt %, about 0.1 wt % to about 10 wt %, about 0.5 wt % to about 10 wt %, about 1 wt % to about 10 wt %, about 2 wt % to about 8 wt %, or about 3 wt % to about 6 wt %.

### Acid

The acid may serve to, together with the oxidizing agent, etch at least a portion of the metal-containing film.

The acid may include an inorganic acid, an organic acid, or any combination thereof.

In one or more embodiments, the acid may include a phosphorus-based inorganic acid, a chlorine-based inorganic acid, a fluorine-based inorganic acid, or any combination thereof. For example, the phosphorus-based inorganic acid may be a phosphate-based inorganic acid.

In one or more embodiments, the acid may include an acid other than nitric acid and sulfuric acid.

In one or more embodiments, the acid may include at least one of the phosphate-based inorganic acid and the chlorine-based inorganic acid.

In one or more embodiments, the acid may include at least one of phosphoric acid, hydrochloric acid, and chloric acid.

In one or more embodiments, the acid may include phosphoric acid.

The amount (weight) of the acid may be, for example per 100 wt % of the composition, in a range of about 0.01 wt % to about 90 wt %, about 0.1 wt % to about 90 wt %, about 1 wt % to about 90 wt %, about 10 wt % to about 90 wt %, about 20 wt % to about 90 wt %, about 30 wt % to about 90 wt %, about 40 wt % to about 90 wt %, about 50 wt % to about 90 wt %, about 60 wt % to about 90 wt %, about 0.01 wt % to about 80 wt %, about 0.1 wt % to about 80 wt %, about 1 wt % to about 80 wt %, about 10 wt % to about 80 wt %, about 20 wt % to about 80 wt %, about 30 wt % to about 80 wt %, about 40 wt % to about 80 wt %, about 50 wt % to about 80 wt %, or about 60 wt % to about 80 wt %.

### Selective Etching Inhibitor

The selective etching inhibitor may interact with various metal atoms in the metal-containing film, which is a target film to be treated, to control (e.g., suppress) an etching speed or the like.

The selective etching inhibitor may include an ammonium compound and a polymer having a nitrogen-containing repeating unit.

### Polymer Having Nitrogen-Containing Repeating Unit Included in Selective Etching Inhibitor

The polymer having a nitrogen-containing repeating unit included in the selective etching inhibitor may be a water-soluble polymer.

The polymer having a nitrogen-containing repeating unit may serve to protect the surface of the metal-containing film through electrostatic attraction. In addition, since the polymer having a nitrogen-containing repeating unit has a bulky three-dimensional structure, at least a portion of the surface of the metal-containing film may be effectively protected. In this regard, by using the composition, the metal-containing film may be treated for various purposes (e.g., etching, cleaning, polishing, etc.).

The nitrogen-containing repeating unit may include a repeating unit represented by Formula 1-1, a repeating unit represented by Formula 1-2, a repeating unit represented by Formula 1-3, a repeating unit represented by Formula 1-4, or any combination thereof:

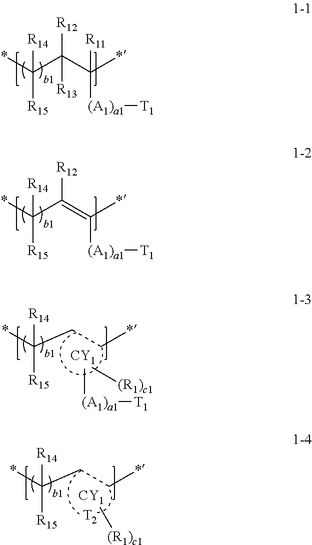

In Formulae 1-1 to 1-3, A₁ may be *—C(R₁₆)(R₁₇)—*′, *—N(R₁₆)—*′, *—C(═O)—*′, *—O—*′, or *—S—*′.

In Formulae 1-1 to 1-3, a1 may be an integer from 0 to 20, and when a1 is 2 or more, two or more of A₁ may be identical to or different from each other. When a1 is 0, *-(A₁)ₐ₁-*′ may be a single bond.

In one or more embodiments, a1 may be 0.

In one or more embodiments, a1 may not be 0.

In one or more embodiments, a1 may be an integer from 0 to 10.

In one or more embodiments, a1 may be an integer from 1 to 5.

In Formulae 1-1 to 1-4, b1 may be an integer from 0 to 10, and when b1 is 2 or more, two or more of *—C(R₁₄)(R₁₅)—*′ may be identical to or different from each other. When b1 is 0, *—C(R₁₄)(R₁₅)—*′ may be a single bond.

In one or more embodiments, b1 may be an integer from 0 to 5.

In Formulae 1-1 to 1-3, T₁ may be *—N(Z₁₁)(Z₁₂), *—[N(Z₁₁)(Z₁₂)(Z₁₃)]⁺[Z₁₄]⁻, a group represented by Formula AN, or a group represented by Formula BN:

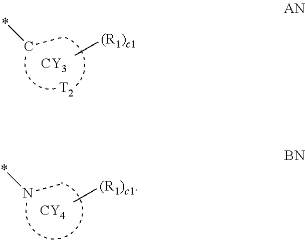

In Formulae 1-3, 1-4, AN, and BN, ring CY₁ to ring CY₄ may each independently be a C₂-C₁₀ cyclic group.

In Formulae 1-4 and AN, T₂ may be *—N(Z₁₁)—*′ or *—[N(Z₁₁)(Z₁₂)]⁺[Z₁₄]⁻—*′. Z₁₁, Z₁₂, and Z₁₄ are each the same as described herein.

In one or more embodiments, T₁ in Formulae 1-1 to 1-3 may be *—N(Z₁₁)(Z₁₂) or *—[N(Z₁₁)(Z₁₂)(Z₁₃)]⁺[Z₁₄]⁻, wherein Zu to Z₁₃ may each be hydrogen.

In one or more embodiments, T₁ in Formulae 1-1 to 1-3 may be *—N(Z₁₁)(Z₁₂) or *—[N(Z₁₁)(Z₁₂)(Z₁₃)]⁺[Z₁₄]⁻, wherein Zu may be hydrogen, and Z₁₂ may not be hydrogen.

In one or more embodiments, T₁ in Formulae 1-1 to 1-3 may be *—N(Z₁₁)(Z₁₂) or *—[N(Z₁₁)(Z₁₂)(Z₁₃)]⁺[Z₁₄]⁻, wherein Z₁₁ and Z₁₂ may each not be hydrogen.

In one or more embodiments, in Formulae 1-1 to 1-3, T₁ may be *—[N(Z₁₁)(Z₁₂)(Z₁₃)]⁺[Z₁₄]⁻, and Z₁₁ to Z₁₃ may each not be hydrogen.

In one or more embodiments, T₁ in Formulae 1-1 to 1-3 may a group represented by Formula AN, and each of Z₁₁ and Z₁₂ in T₂ of Formula AN may be hydrogen.

In one or more embodiments, T₁ in Formulae 1-1 to 1-3 may a group represented by Formula AN, and Z₁₁ in T₂ of Formula AN may not be hydrogen.

In one or more embodiments, T₁ in Formulae 1-1 to 1-3 may be a group represented by Formula AN, and T₂ in Formula AN may be *—[N(Z₁₁)(Z₁₂)]⁺[Z₁₄]⁻—*′, wherein each of Z₁₁ and Z₁₂ may not be hydrogen.

In one or more embodiments, each of Z₁₁ and Z₁₂ in T₂ of Formula 1-4 may be hydrogen.

In one or more embodiments, in T₂ of Formula 1-4, Z₁₁ may not be hydrogen, and Z₁₂ may be hydrogen.

In one or more embodiments, T₂ in Formula 1-4 may be *—[N(Z₁₁)(Z₁₂)]⁺[Z₁₄]⁻—*′, wherein each of Z₁₁ and Z₁₂ may not be hydrogen.

In Formulae 1-3, 1-4, AN, and BN, c1 indicates the number of R₁, and may be an integer from 0 to 10. When c1 is 2 or more, two or more of R₁ may be identical to or different from each other.

In one or more embodiments, CY₁ in Formula 1-3 may be a cyclopropane group, a cyclobutane group, a cyclopentane group, a cyclohexane group, a cycloheptane group, a cyclooctane group, an oxirane group, an oxetane group, a tetrahydrofuran group, or a tetrahydropyran group.

In one or more embodiments, ring CY₂ in Formula 1-4 may be a saturated cyclic group having 4, 5, 6, or 7 carbon atoms.

In one or more embodiments, in Formula AN, i) T₂ may be *—N(Z₁₁)—*′, and ring CY₃ may be a pyrrole group, an imidazole group, a pyrazole group, an aziridine group, an azetidine group, a pyrrolidine group, or a piperidine group, or ii) T₂ may be *—[N(Z₁₁)(Z₁₂)]⁺[Z₁₄]⁻—*′, and ring CY₃ may be a saturated cyclic group having 4, 5, 6, or 7 carbon atoms.

In one or more embodiments, ring CY₄ in Formula BN may be a pyrrole group, an imidazole group, a pyrazole group, an aziridine group, an azetidine group, a pyrrolidine group, or a piperidine group.

In one or more embodiments, R₁, R₁₁, R₁₂, R₁₃, R₁₄, R₁₅, R₁₆, R₁₇, Z₁₁, Z₁₂, and Z₁₃ may each independently be: 1) hydrogen, deuterium, *—F, *—Cl, *—Br, *—I, *—OH, *—SH, *—C(═O)-Q₁, *—NH—C(═O)-Q₁, *—C(═O)—O-Q₁, *—SO₂-Q₁, *—P(═O)-(Q₁)(Q₂), *—[N(Q₁)(Q₂)(Q₃)]⁺[Q₄], *—(O—CH₂CH₂)ₙ₁—OH, or any combination thereof; and/or 2) a C₁-C₃₀ alkyl group, a C₁-C₃₀ alkoxy group, a C₂-C₃₀ alkenyl group, a C₃-C₃₀ carbocyclic group, or a C₁-C₃₀ heterocyclic group, each unsubstituted or substituted with deuterium, *—F, *—Cl, *—Br, *—I, *—OH, *—SH, *—C(═O)-Q₁₁, *—NH—C(═O)-Q₁₁, *—C(═O)—O-Q₁₁, *—SO₂-Q₁₁, *—P(═O)-(Q₁₁)(Q₁₂), *—N(Q₁₁)(Q₁₂), *[N(Q₁₁)(Q₁₂)(Q₁₃)]⁺[Q₁₄], *—(O—CH₂CH₂)ₙ₂—OH, a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or any combination thereof.

In one or more embodiments, n1 and n2 may each independently be an integer from 1 to 20, for example, 1 to 10, 1 to 6, or 1 to 3.

In one or more embodiments, two or more of R₁, R₁₁, R₁₂, R₁₃, R₁₄, R₁₅, R₁₆, R₁₇, Z₁₁, Z₁₂, and Z₁₃ may optionally be bonded together to form a cyclic group having 2 to 10 carbon atoms, and Q₁ to Q₃ and Q₁₁ to Q₁₃ may each independently be: hydrogen, deuterium, *—F, *—Cl, *—Br, *—I, *—OH, *—SH, *—C(═O)—H, *—C(═O)—OH, *—C(—O)—NH₂, *—C(═O)—NH(CH₃), *—C(═O)—N(CH₃)₂, *—NH—C(—O)—NH₂, *—NH—C(═O)—NH(CH₃), *—NH—C(═O)—N(CH₃)₂, *—NH₂, *—NH(CH₃), *—N(CH₃)₂, a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or any combination thereof. Each of the C₁-C₃₀ alkyl group, the C₁-C₃₀ alkoxy group, the C₂-C₃₀ alkenyl group, the C₃-C₃₀ carbocyclic group, and/or the C₁-C₃₀ heterocyclic group may be unsubstituted or substituted with deuterium, *—F, *—Cl, *—Br, *—I, *—OH, *—SH, *—C(═O)—H, *—C(═O)—OH, *—C(—O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), *—N(CH₃)₂, a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or any combination thereof.

The C₃-C₃₀ carbocyclic group may be, for example, a cyclopropyl group, a cyclobutyl group, a cyclopentyl group, a cyclohexyl group, a cycloheptyl group, a cyclooctyl group, a phenyl group, a naphthyl group, and/or the like.

The C₁-C₃₀ heterocyclic group may be, for example, an oxiranyl group, an oxetanyl group, a tetrahydrofuranyl group, a tetrahydropyranyl group, a pyridinyl group, a pyrimidinyl group, and/or the like.

[Z₁₄]⁻, [Q₄]⁻, and [Q₁₄]⁻ may each be an anion.

For example, [Z₁₄]⁻, [Q₄]⁻, and [Q₁₄]⁻ may each independently be hydroxide ([OH]⁻), borate ([B(OH)₄]⁻), fluoride ([F]⁻), chloride ([Cl]⁻), bromide ([Br]⁻), iodide ([I]⁻), hydrogen sulfate ([HSO₄]⁻), nitrate ([NO₃]⁻), formate ([HCOO]⁻), acetate ([CH₃COO]⁻), or dihydrogen phosphate ([H₂PO₄]⁻).

In the present specification, * and *′ each indicate a binding site to a neighboring atom unless otherwise defined.

In one or more embodiments, the repeating unit represented by Formula 1-3 may be represented by one of Formulae 1-3(1) to 1-3(8):

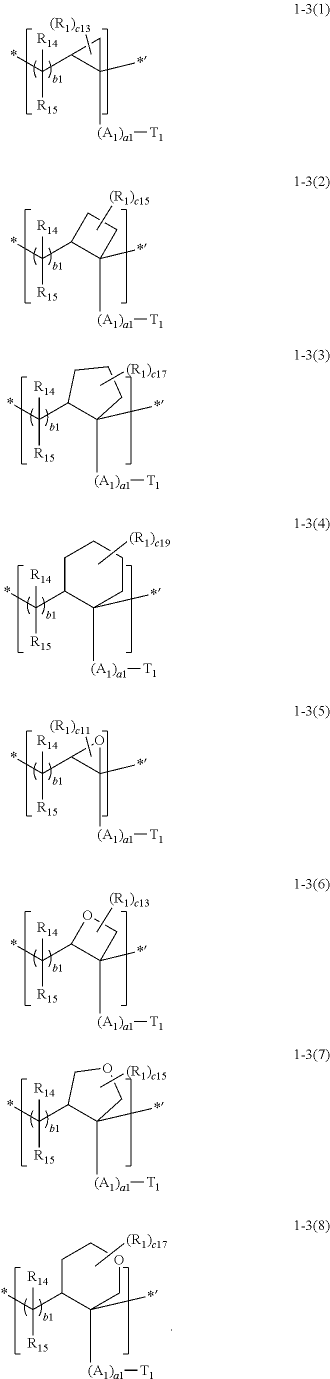

In Formulae 1-3(1) to 1-3(8), A₁, a1, b1, T₁, R₁, R₁₄, and R₁₅ are each the same as the description herein, c11 may be 0 or 1, c13 may be an integer from 0 to 3, c15 may be an integer from 0 to 5, c17 may be an integer from 0 to 7, and c19 may be an integer from 0 to 9.

In one or more embodiments, the repeating unit represented by Formula 1-4 may be represented by one of Formulae 1-4(1) to 1-4(3):

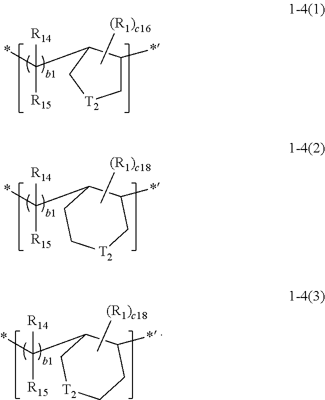

In Formulae 1-4(1) to 1-4(3), b1, R₁, R₁₄, R₁₅, and T₂ are each the same as the description herein, c16 may be an integer from 0 to 6, and c18 may be an integer from 0 to 8.

In one or more embodiments, the group represented by Formula AN may be represented by one of Formulae AN(1) to AN(12):

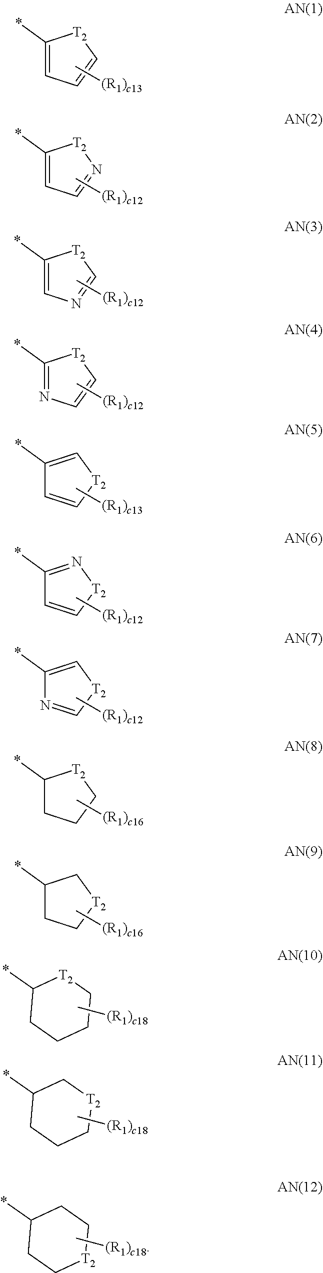

In Formulae AN(1) to AN(12), R₁ and T₂ are each the same as the description herein, c12 may be an integer from 0 to 2, c13 may be an integer from 0 to 3,
c16 may be an integer from 0 to 6, and c18 may be an integer from 0 to 8.

In one or more embodiments, the group represented by Formula BN may be represented by one of Formulae BN(1) to BN(7):

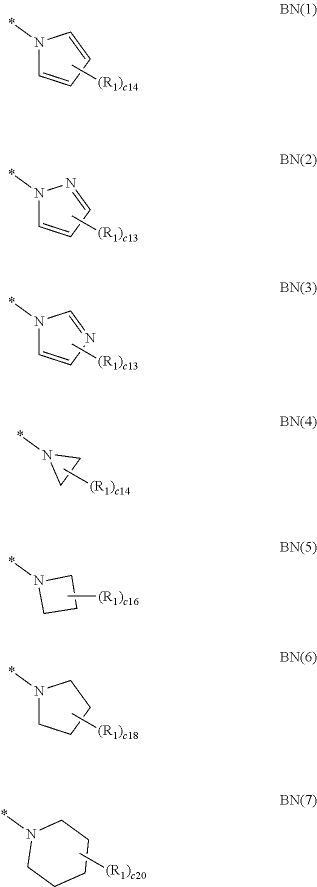

In Formulae BN(1) to BN(7), R₁ is the same as the description herein, and c13 may be an integer from 0 to 3, c14 may be an integer from 0 to 4,
c16 may be an integer from 0 to 6, c18 may be an integer from 0 to 8, and c20 may be an integer from 0 to 10.

In one or more embodiments, the polymer having a nitrogen-containing repeating unit may be a homopolymer (for example, Polymer 1 etc. described herein).

In one or more embodiments, the polymer having a nitrogen-containing repeating unit may be a copolymer. The copolymer may be an alternating copolymer, a block copolymer, a random copolymer, a graft copolymer, and/or the like.

In one or more embodiments, the polymer having a nitrogen-containing repeating unit may be a copolymer having a combination of two or more nitrogen-containing repeating units that are different from each other, as the nitrogen-containing repeating unit (for example, Polymer C1 etc. described herein). In one or more embodiments, the copolymer may only have the combination of two or more nitrogen-containing repeating units that are different from each other, as repeating units. In one or more embodiments, the polymer having a nitrogen-containing repeating unit may be a copolymer having a first nitrogen-containing repeating unit and a second nitrogen-containing repeating unit that are different from each other. The first nitrogen-containing repeating unit and the second nitrogen-containing repeating unit are each the same as the description in connection with the nitrogen-containing repeating unit. For example, the first nitrogen-containing repeating unit and the second nitrogen-containing repeating unit may be different from each other, wherein the first nitrogen-containing repeating unit and the second nitrogen-containing repeating unit may each independently be selected from the repeating unit represented by Formula 1-1, the repeating unit represented by Formula 1-2, the repeating unit represented by Formula 1-3, and/or the repeating unit represented by Formula 1-4. In one or more embodiments, the copolymer may only have the first nitrogen-containing repeating unit and the second-containing repeating unit as repeating units.

In one or more embodiments, the polymer having a nitrogen-containing repeating unit may be a copolymer further including at least one additional repeating unit that is different from the nitrogen-containing repeating unit, in addition to the nitrogen-containing repeating unit (for example, Polymer C4 etc. described herein). The additional repeating unit is not encompassed in the nitrogen-containing repeating unit as described herein.

In one or more embodiments, the additional repeating unit may include a repeating unit derived from an ether-containing compound, a repeating unit derived from an alkene-containing compound, a repeating unit derived from a sulfur dioxide (sulfone)-containing compound, a repeating unit derived from a phosphate-containing compound, a repeating unit derived from an amide-containing compound, a repeating unit derived from a carboxylic acid-containing compound, or any combination thereof.

In one or more embodiments, the additional repeating unit may include a repeating unit represented by Formula 2-1, a repeating unit represented by Formula 2-2, a repeating unit represented by Formula 2-3, a repeating unit represented by Formula 2-4, a repeating unit represented by 2-5, a repeating unit represented by Formula 2-6, or any combination thereof:

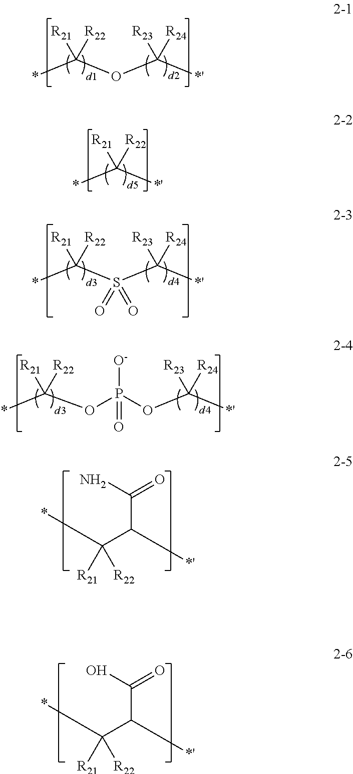

In Formulae 2-1 to 2-6, R₂₁ to R₂₄ may each independently be: hydrogen, deuterium, *—F, *—Cl, *—Br, *—I, *—OH, *—SH, *—C(═O)-Q₂₁, *—NH—C(═O)-Q₂₁, *—C(═O)—O-Q₂₁, *—SO₂-Q₂₁, *—P(═O)-(Q₂₁)(Q₂₂), *—N(Q₂₁)(Q₂₂), a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or any combination thereof, wherein the C₁-C₃₀ alkyl group, the C₁-C₃₀ alkoxy group, the C₂-C₃₀ alkenyl group, the C₃-C₃₀ carbocyclic group, and/or the C₁-C₃₀ heterocyclic group may each be unsubstituted or substituted with deuterium, *—F, *—Cl, *—Br, *—I, *—OH, *—SH, *—C(—O)-Q₃₁, *—NH—C(═O)-Q₃₁, *—C(═O)—O-Q₃₁, *—SO₂-Q₃₁, *—P(═O)-(Q₃₁)(Q₃₂), *—N(Q₃₁)(Q₃₂), a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or any combination thereof; Q₂₁, Q₂₂, Q₃₁, and Q₃₂ may each independently be: hydrogen, deuterium, *—F, *—Cl, *—Br, *—I, *—OH, *—SH, *—C(—O)—H, *—C(═O)—OH, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), *—N(CH₃)₂, a C₁-C₃₀ alkyl group, a C₁-C₃₀ alkoxy group, a C₂-C₃₀ alkenyl group, a C₃-C₃₀ carbocyclic group, or a C₁-C₃₀ heterocyclic group, wherein the C₁-C₃₀ alkyl group, the C₁-C₃₀ alkoxy group, the C₂-C₃₀ alkenyl group, the C₃-C₃₀ carbocyclic group, and/or the C₁-C₃₀ heterocyclic group each unsubstituted or substituted with deuterium, *—F, *—Cl, *—Br, *—I, *—OH, *—SH, *—C(═O)—H, *—C(═O)—OH, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), *—N(CH₃)₂, a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or any combination thereof; d1 to d4 may each independently be an integer from 0 to 20 (e.g., an integer from 0 to 10), and the sum of d1 and d2 may be 1 or more,
d5 may be an integer from 1 to 20 (e.g., an integer from 1 to 20); and * and *′ each indicate a binding site to a neighboring atom.

For example, R₂₁ and R₂₂ may each independently be: hydrogen, deuterium, *—F, *—Cl, *—Br, *—I, *—OH, *—SH, *—C(═O)-Q₂₁, *—NH—C(═O)-Q₂₁, *—C(═O)—O-Q₂₁, *—SO₂-Q₂₁, *—P(═O)-(Q₂₁)(Q₂₂), *—N(Q₂₁)(Q₂₂), and/or a C₁-C₁₀ alkyl group unsubstituted or substituted with deuterium, *—F, *—Cl, *—Br, *—I, *—OH, *—SH, *—C(═O)-Q₃₁, *—NH—C(═O)-Q₃₁, *—C(═O)—O-Q₃₁, *—SO₂-Q₃₁, *—P(═O)-(Q₃₁)(Q₃₂), *—N(Q₃₁)(Q₃₂), a C₁-C₁₀ alkyl group, or any combination thereof; and Q₂₁, Q₂₂, Q₃₁, and Q₃₂ may each independently be hydrogen, *—OH, *—SH, *—C(═O)—H, *—C(—O)—OH, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), *—N(CH₃)₂, and/or a C₁-C₁₀ alkyl group unsubstituted or substituted with deuterium, *—F, *—Cl, *—Br, *—I, *—OH, *—SH, *—C(═O)—H, *—C(═O)—OH, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), *—N(CH₃)₂, a C₁-C₁₀ alkyl group, or any combination thereof.

In the copolymer, the molar ratio of the nitrogen-containing repeating unit to the additional repeating unit may be in a range of about 1:99 to about 99:1, about 10:90 to about 90:10, about 20:80 to about 80:20, about 30:70 to about 70:30, or about 40:60 to about 60:40.

The weight average molecular weight of the polymer having a nitrogen-containing repeating unit may be in a range of about 200 g/mol to about 100,000 g/mol, for example, about 400 g/mol to about 10,000 g/mol, about 500 g/mol to about 5,000 g/mol, about 600 g/mol to about 3,000 g/mol, about 700 g/mol to about 2,500 g/mol, or about 1000 g/mol to about 2000 g/mol. The weight average molecular weight may be measured by using, for example, gel permeation chromatography (GPC), and may be a value calculated by using polystyrene as a standard.

The selective etching inhibitor may include one type of the polymer having a nitrogen-containing repeating unit, or two or more types of the polymer having a nitrogen-containing repeating unit. For example, the selective etching inhibitor may include, as the polymer having a nitrogen-containing repeating unit, only Polymer I or a mixture of e.g., Polymer 1 and Polymer 2 which will be described later.

In one or more embodiments, the polymer having a nitrogen-containing repeating unit may be one of Polymers 1 to 310 and C1 to C14:

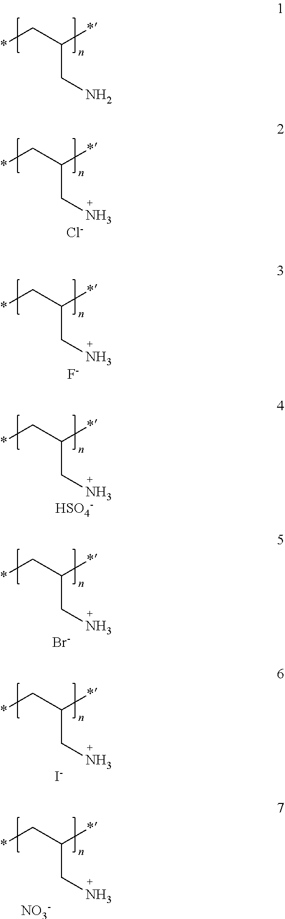

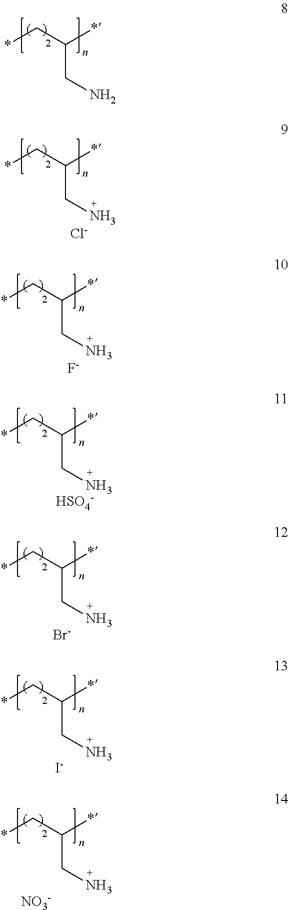

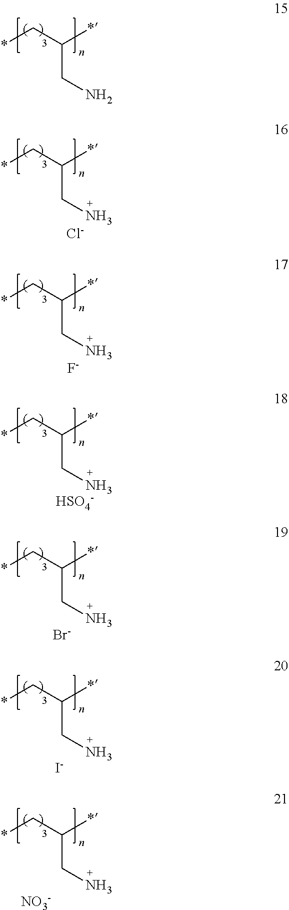

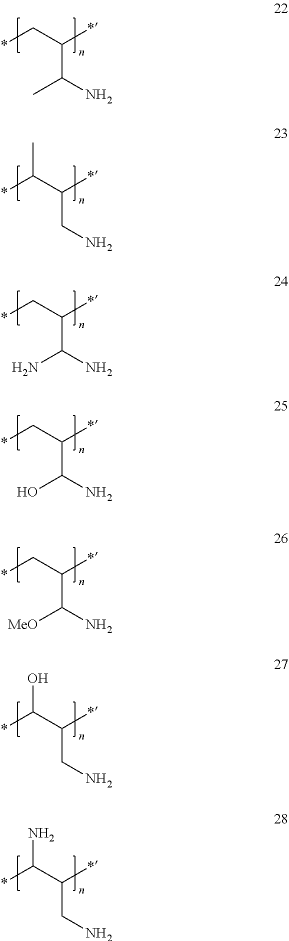

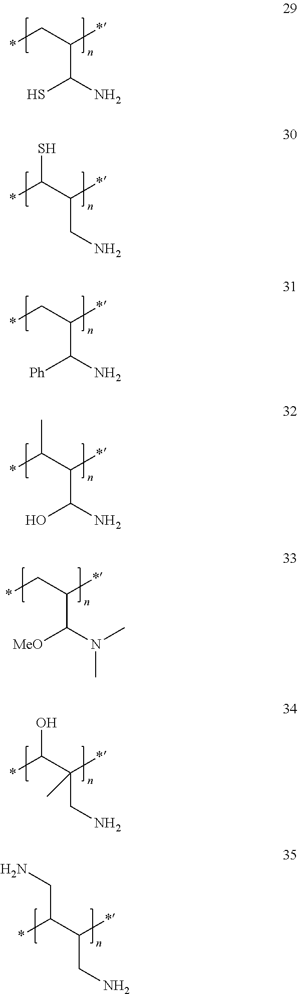

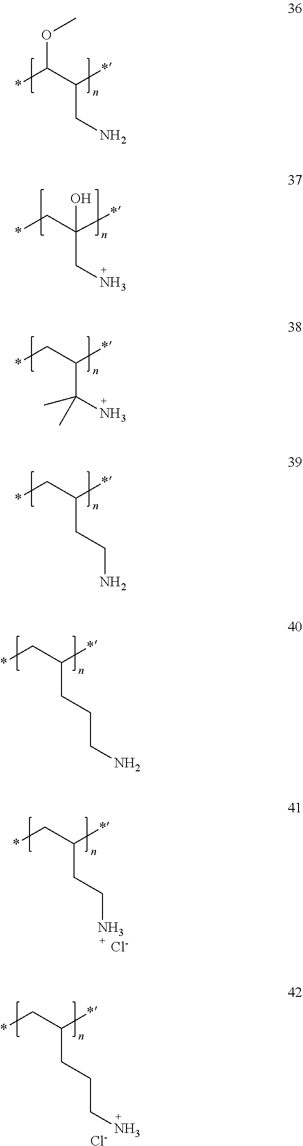

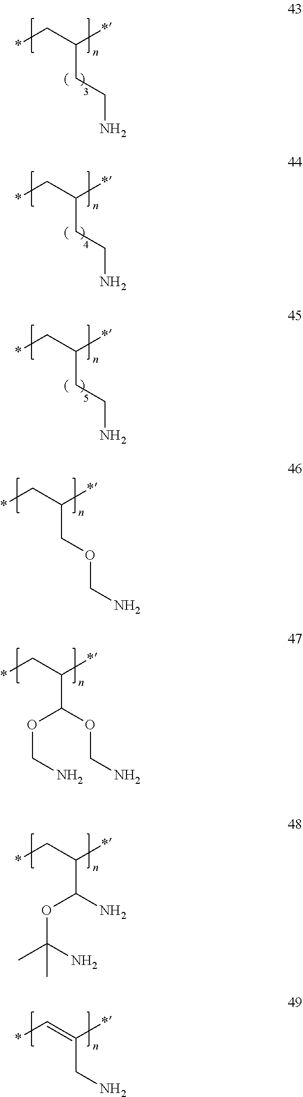

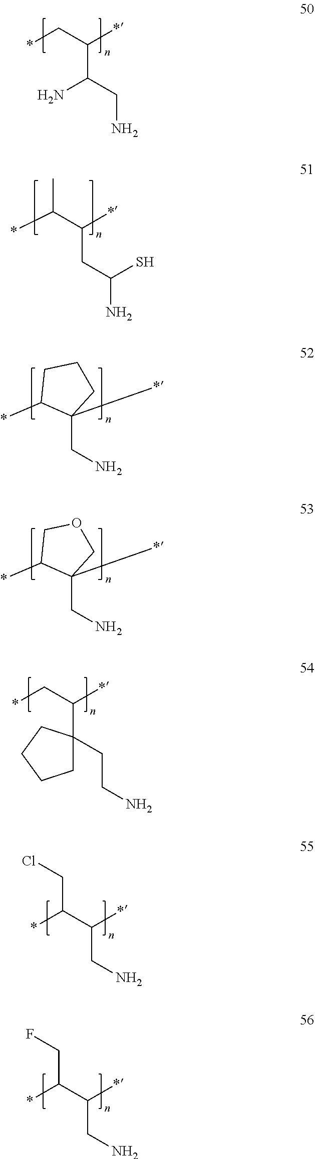

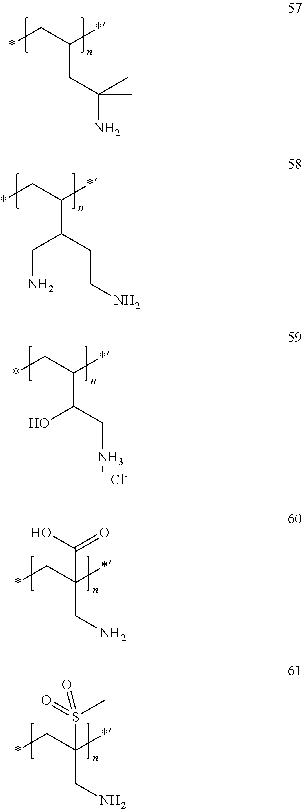

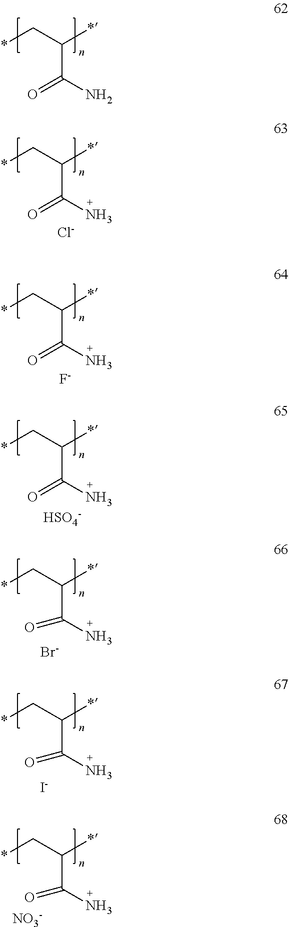

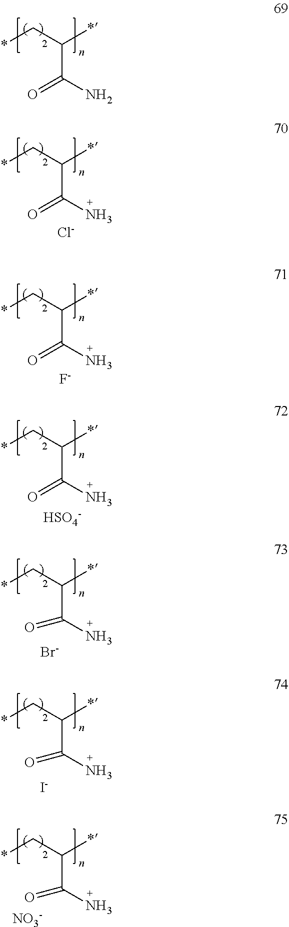

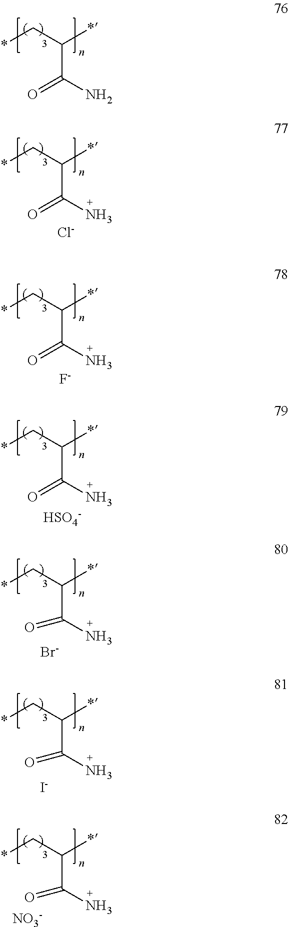

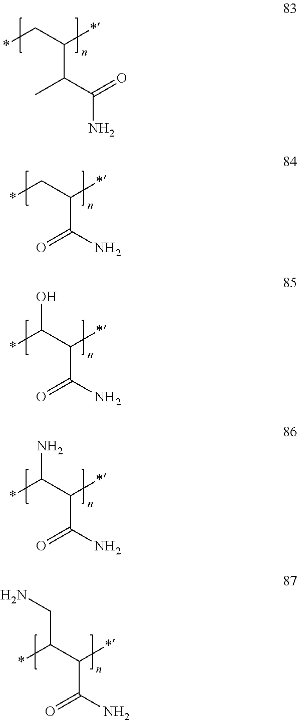

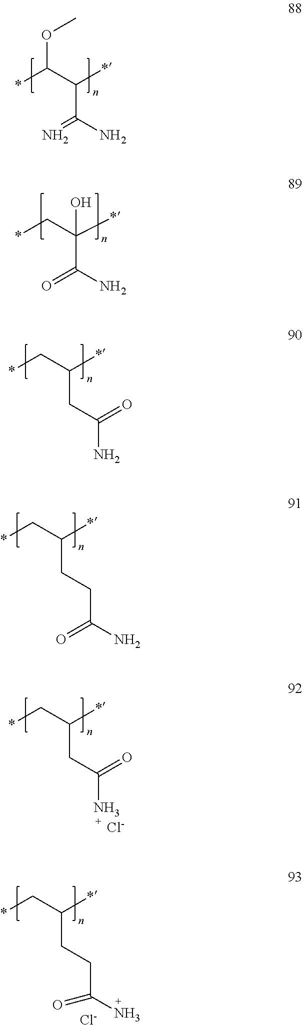

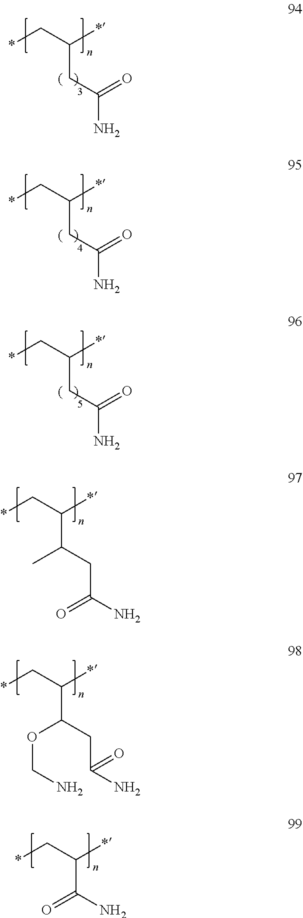

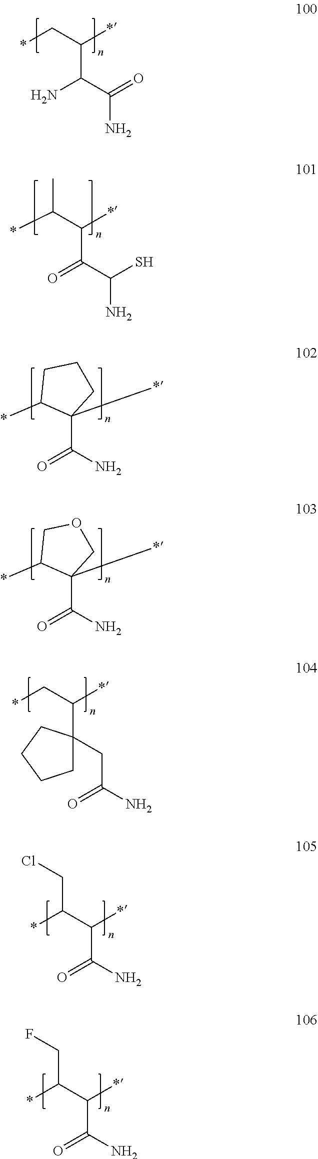

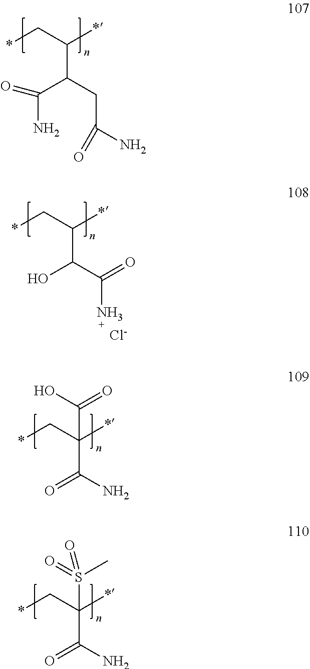

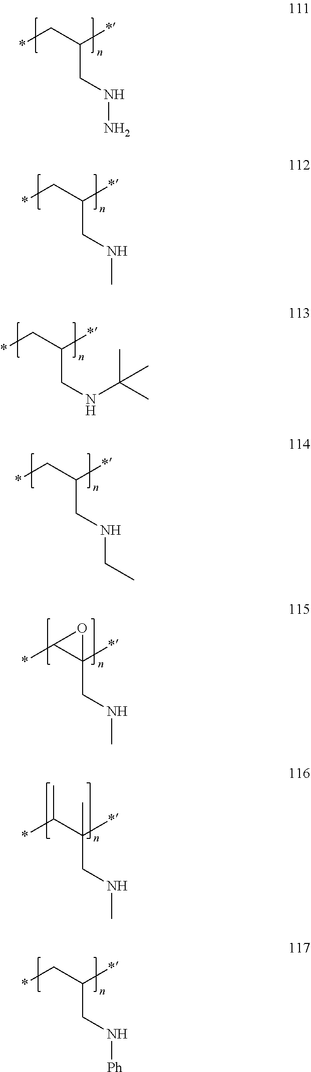

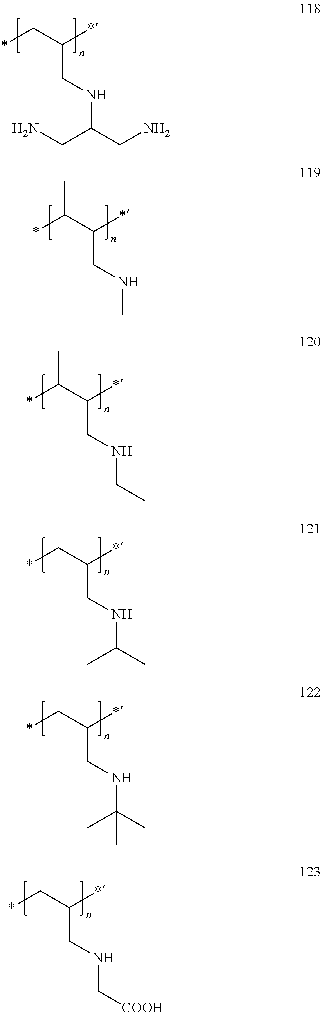

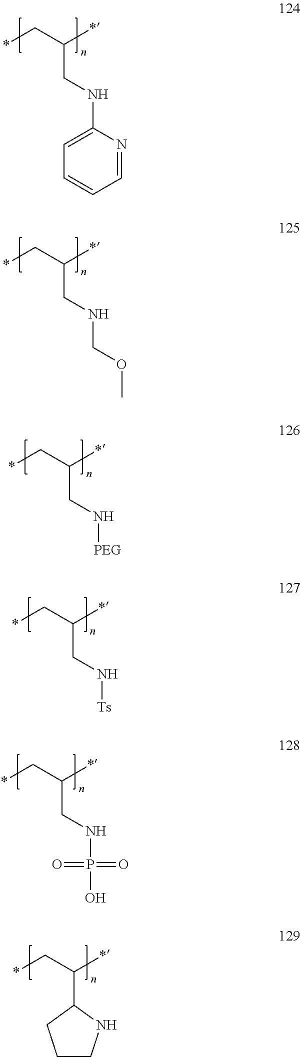

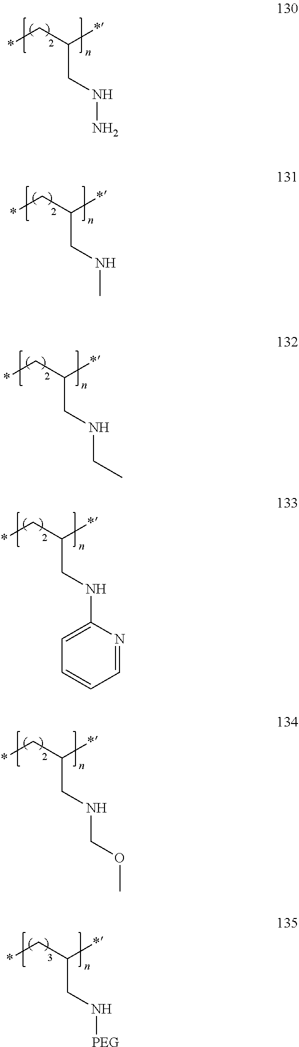

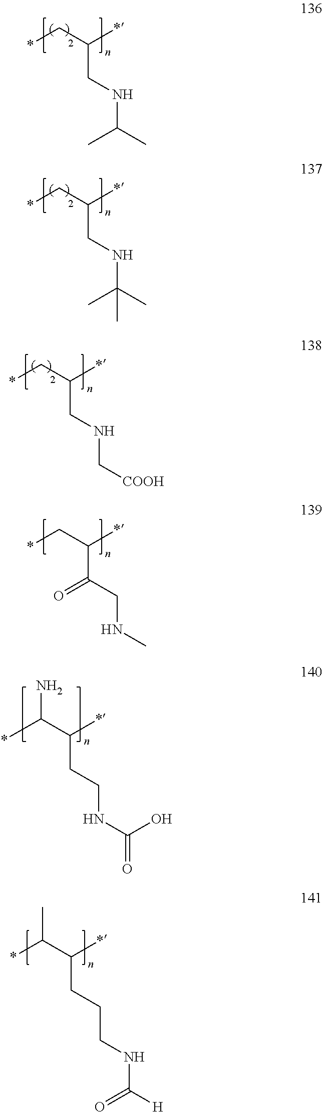

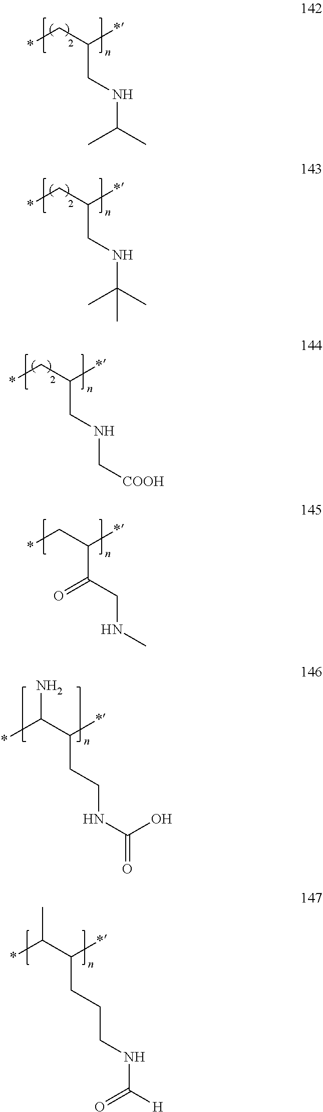

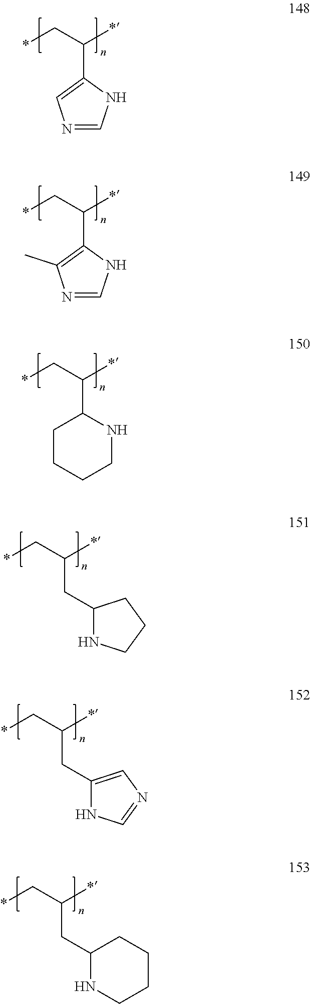

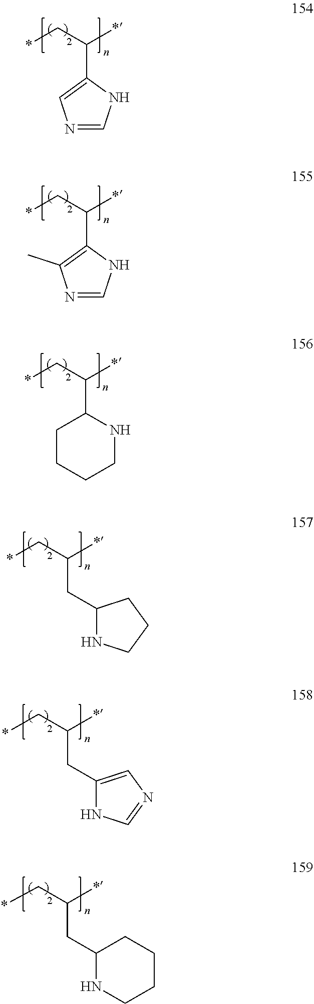

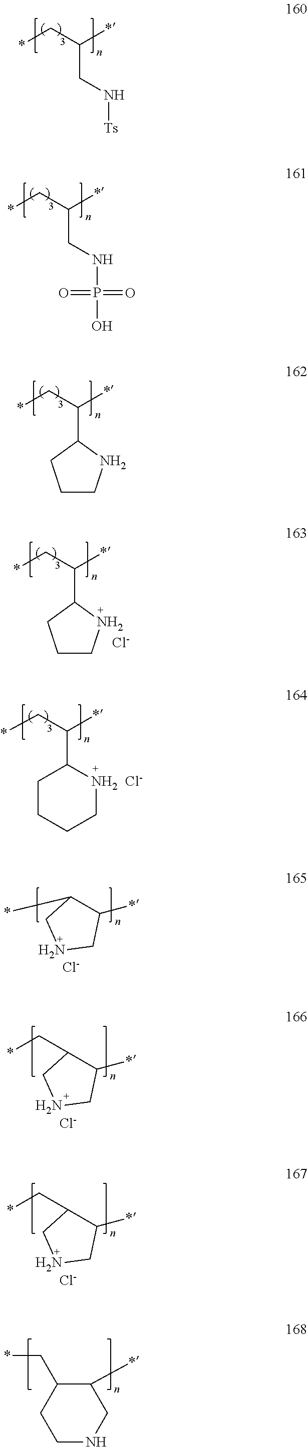

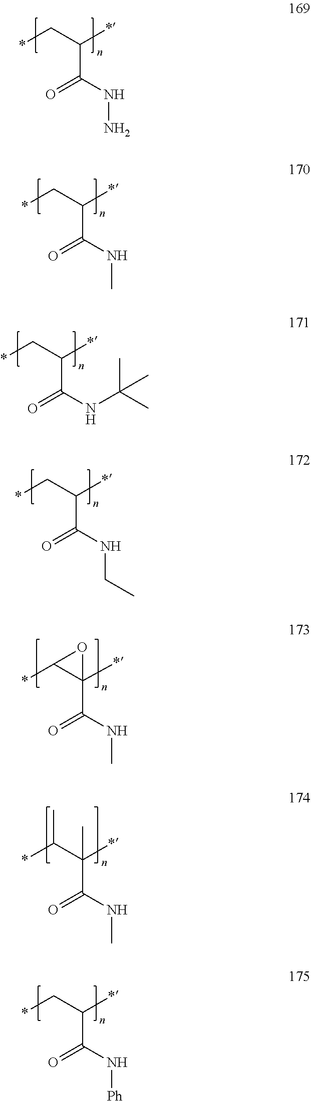

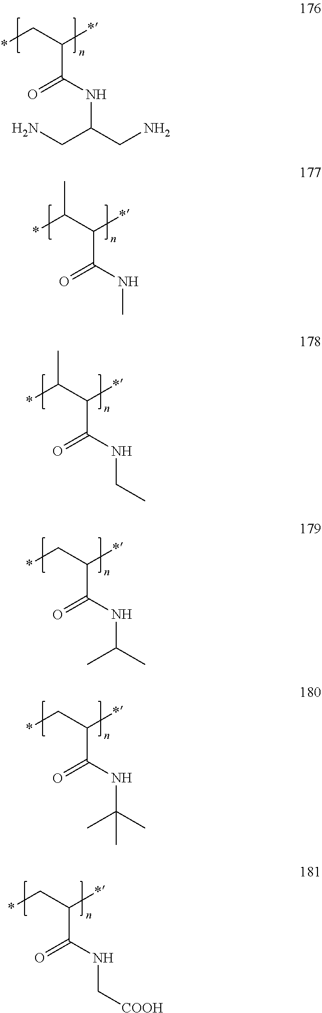

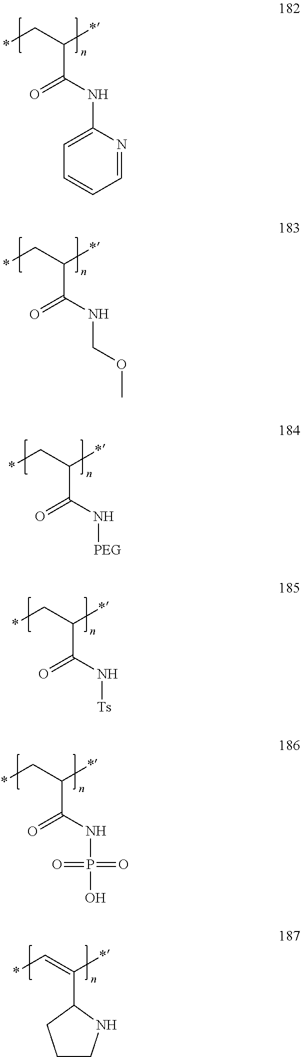

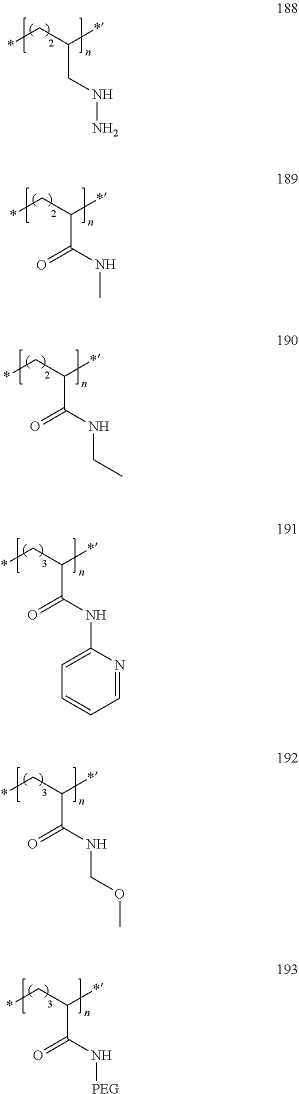

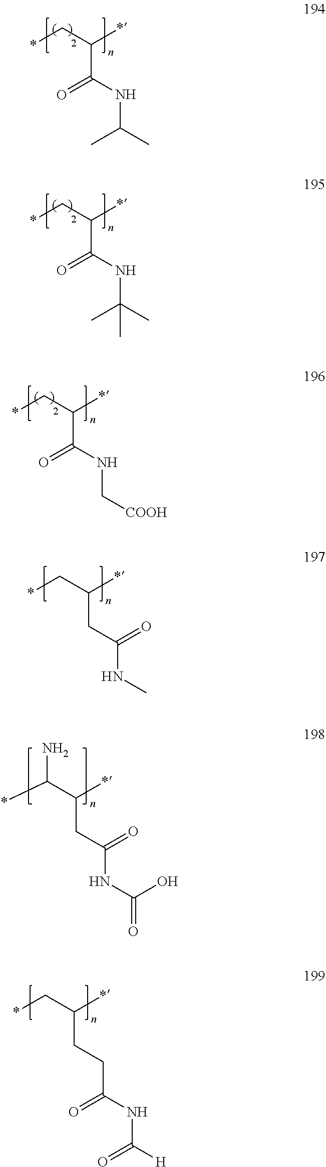

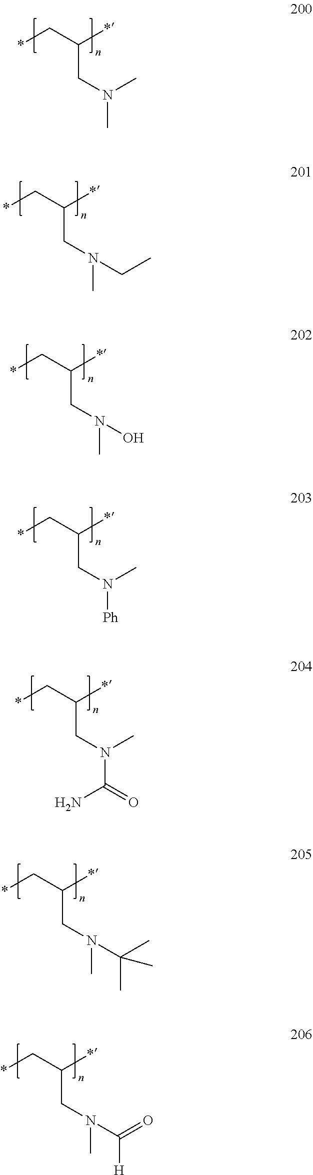

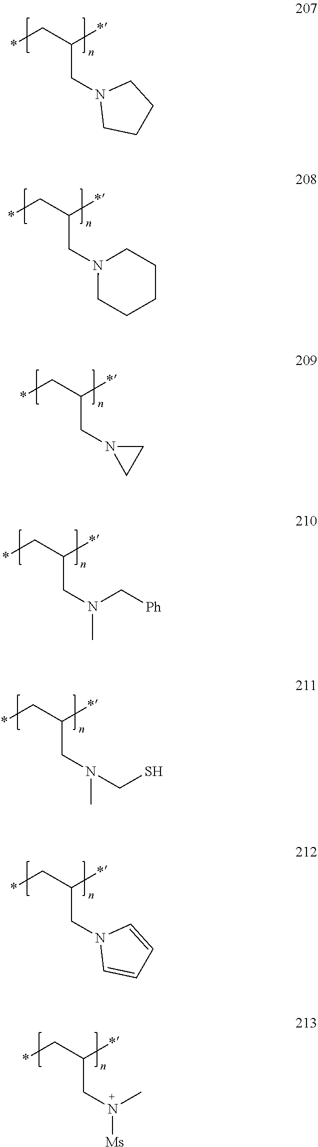

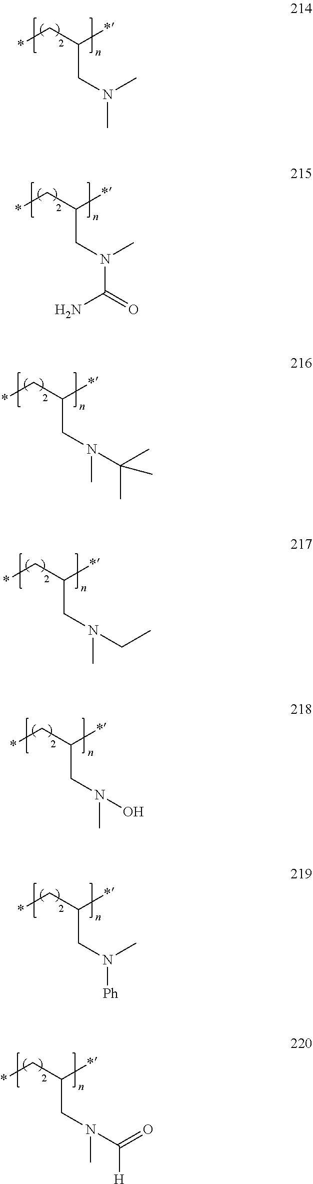

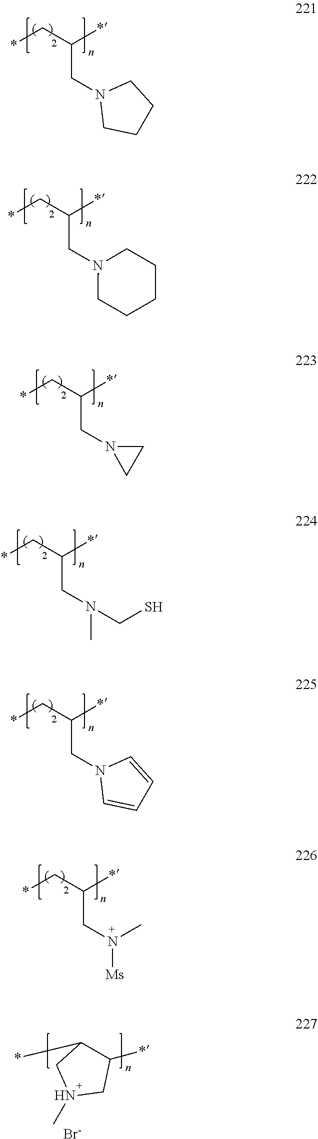

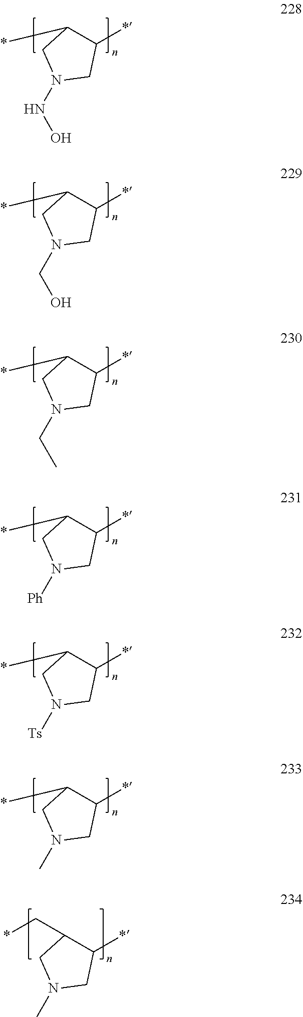

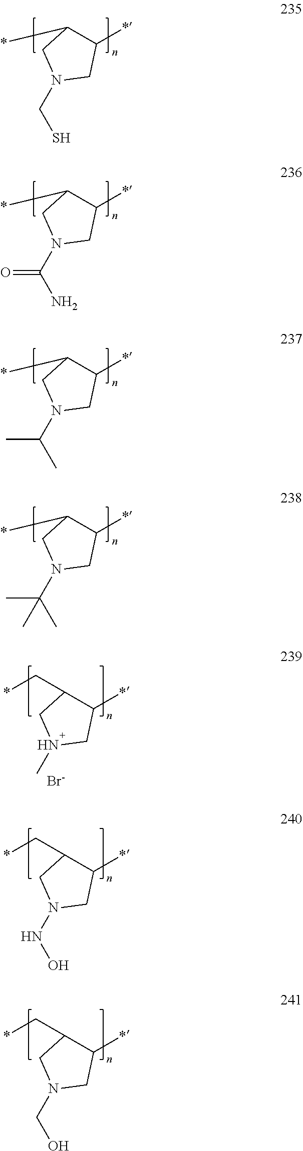

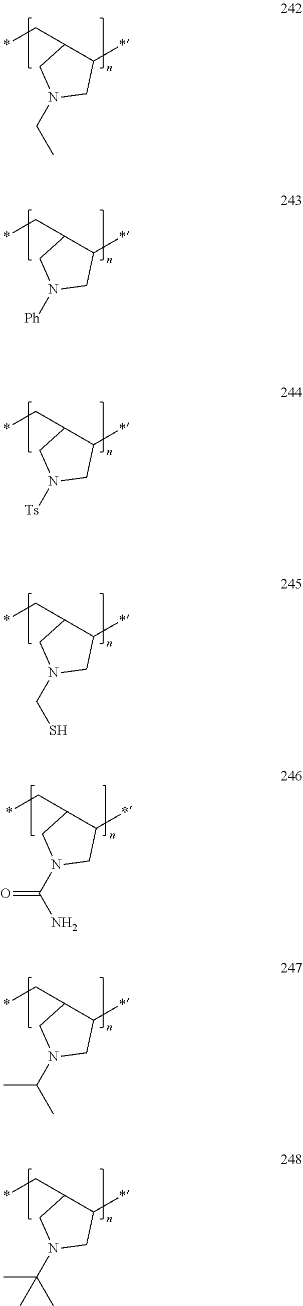

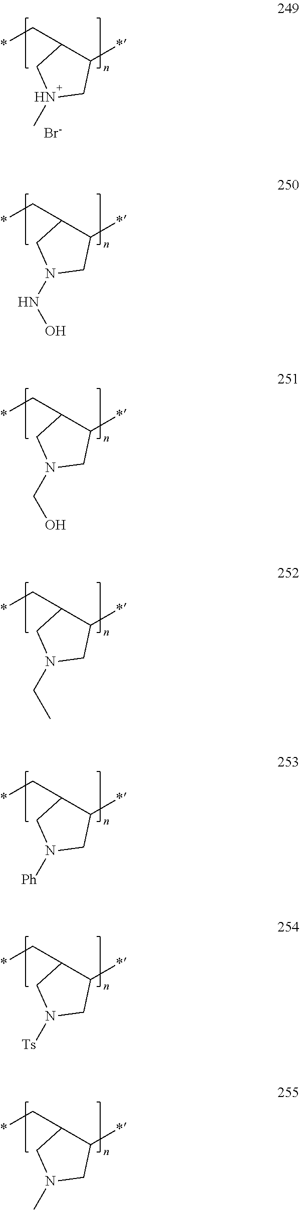

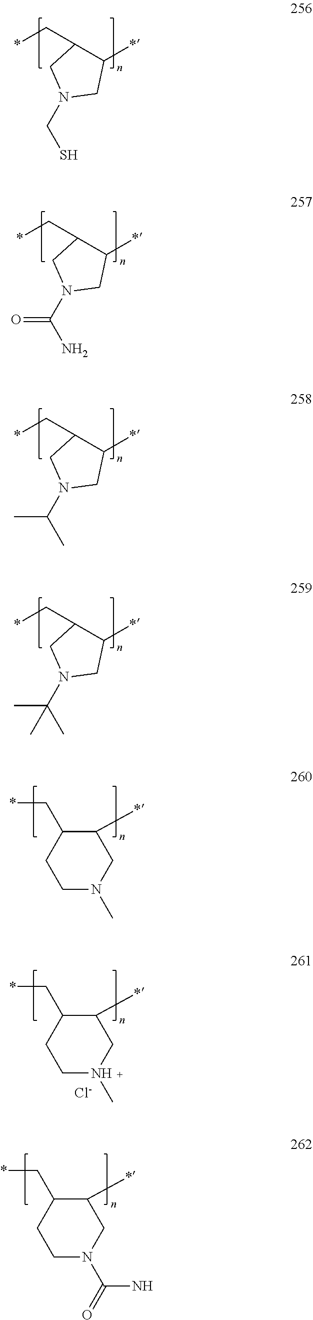

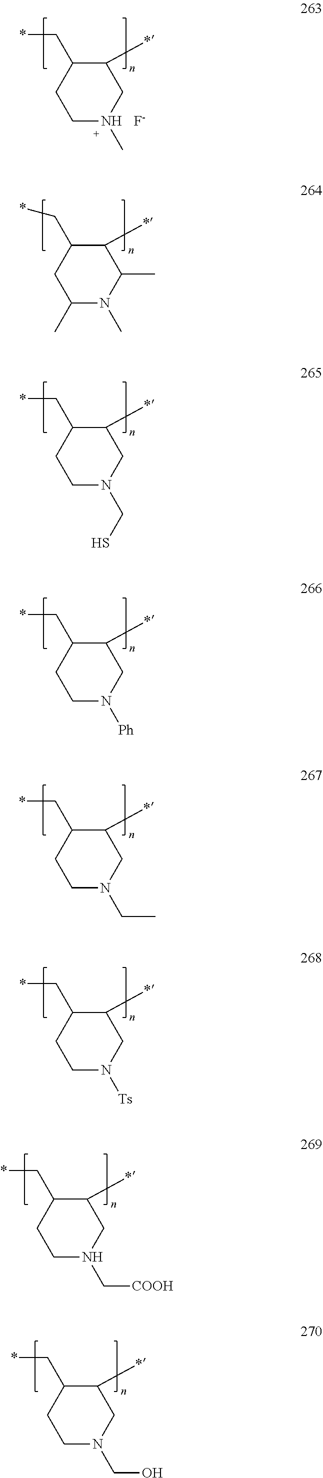

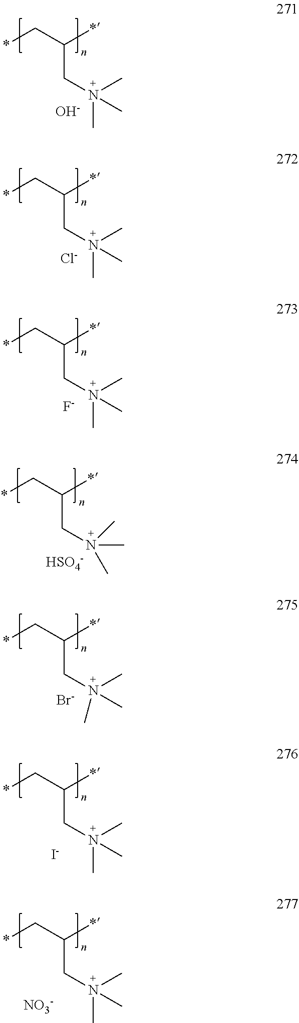

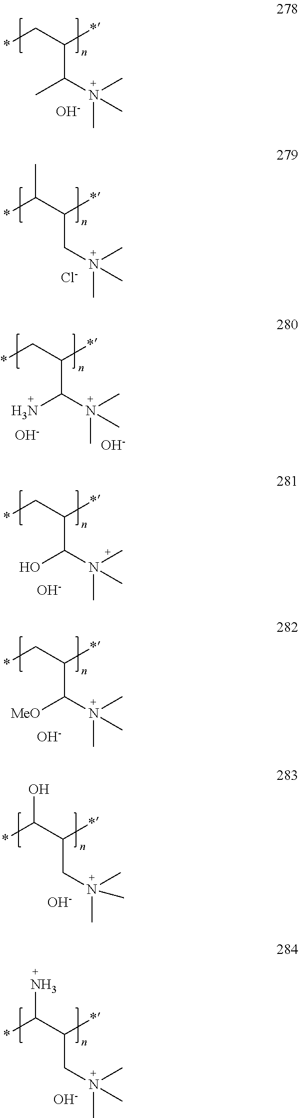

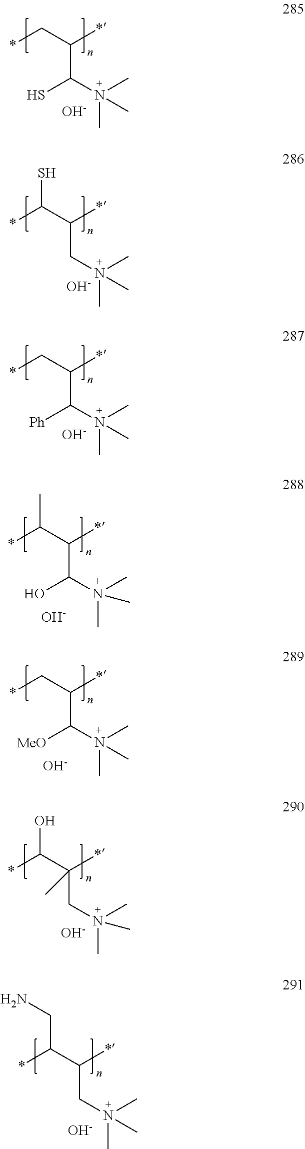

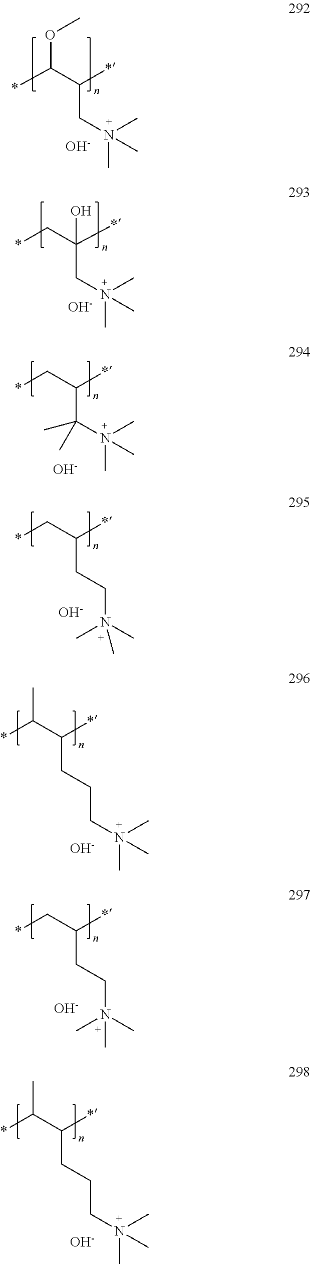

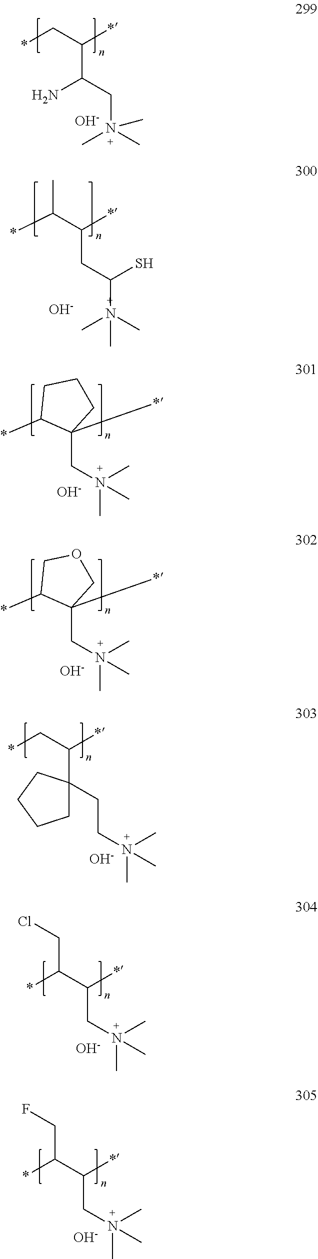

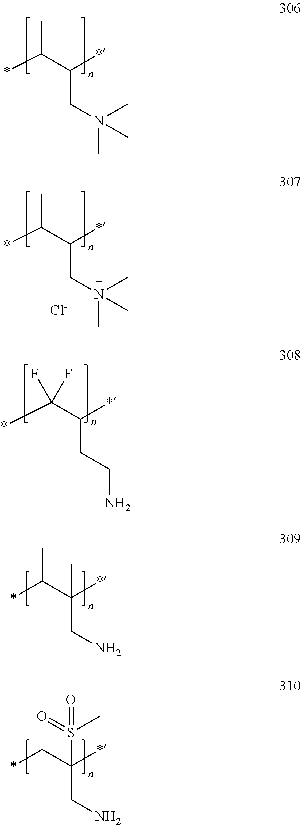

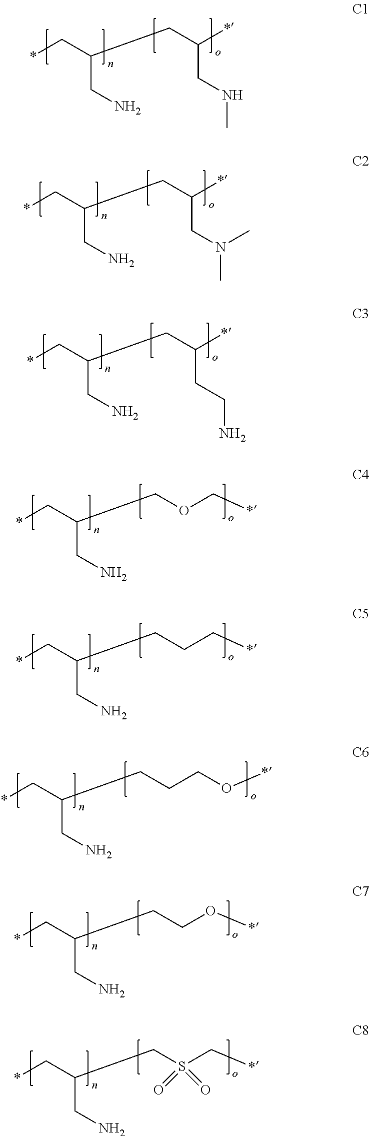

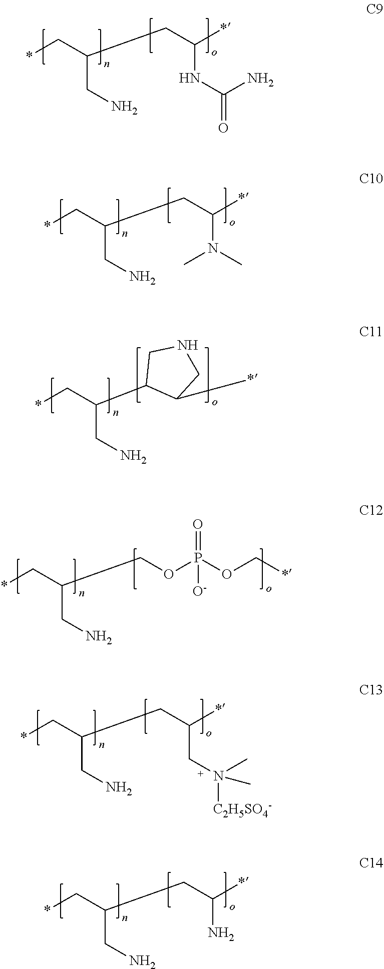

In Polymers 1 to 310 and C1 to C14, OMe indicates a methoxy group, Ph indicates a phenyl group, PEG indicates a polyethylene glycol group (*—(O—CH₂—CH₂)ₙ₁—OH) (where n1 is an integer from 1 to 20, for example, 2 to 10, or 3 to 6), Ts indicates a toluenesulfonyl group (*—S(═O)₂—(C₆H₄)—CH₃), Ms indicates a methylsulfonyl group (*—S(═O)₂—CH₃), and n and o may each independently be an integer from 2 to 10,000, for example, 3 to 1000, 4 to 500, 5 to 200, 6 to 100, 7 to 50, 8 to 25, 9 to 20, or 10 to 15.

Polymers 1 to 310 and C1 to C14 may each have the weight average molecular weight within the ranges described herein.

In one or more embodiments, the polymer having a nitrogen-containing repeating unit may be selected from an allylamine maleic acid copolymer, a diallyldimethyl-ammoniumchloride sulfur dioxide copolymer, a diallylamine sulfur dioxide copolymer, a diallylamine hydrochloride sulfur dioxide copolymer, a diallylmethylethyl-ammoniumethylsulfate sulfur dioxide copolymer, a diallylamine acetate sulfur dioxide copolymer, a methyldiallylamine hydrochloride sulfur dioxide copolymer, a diallylamine acrylamide copolymer, a diallylamine hydrochloride acrylamide copolymer, a diallyldimethyl-ammoniumchloride acrylamide copolymer, a diallylamine maleic acid copolymer, a diallylamine hydrochloride maleic acid copolymer, a diallylamine amidesulfate maleic acid copolymer, a methyldiallylamine maleic acid copolymer, a diallylmethylethyl-ammoniumethylsulfate maleic acid copolymer, a diallyldimethyl ammoniumchloride maleic acid copolymer, a diallylamine maleic acid sulfur dioxide copolymer, a diallyldimethyl ammoniumchloride maleic acid sulfur dioxide copolymer, or any combination thereof. The polymers may each have the weight average molecular weight within the ranges described herein.

The amount (weight) of the nitrogen-containing repeating unit may be, based on the solids of the polymer having a nitrogen-containing repeating unit, for example, per 100 wt % of the composition, in a range of about 0.001 wt % to about 20 wt %, about 0.001 wt % to about 15 wt %, about 0.001 wt % to about 10 wt %, about 0.001 wt % to about 7 wt %, about 0.001 wt % to about 5 wt %, about 0.001 wt % to about 4 wt %, about 0.001 wt % to about 3 wt %, about 0.001 wt % to about 2 wt %, about 0.001 wt % to about 1 wt %, about 0.001 wt % to about 0.5 wt %, about 0.001 wt % to about 0.1 wt %, about 0.005 wt % to about 20 wt %, about 0.005 wt % to about 15 wt %, about 0.005 wt % to about 10 wt %, about 0.005 wt % to about 7 wt %, about 0.005 wt % to about 5 wt %, about 0.005 wt % to about 4 wt %, about 0.005 wt % to about 3 wt %, about 0.005 wt % to about 2 wt %, about 0.005 wt % to about 1 wt %, about 0.005 wt % to about 0.5 wt %, about 0.005 wt % to about 0.1 wt %, about 0.01 wt % to about 20 wt %, about 0.01 wt % to about 15 wt %, about 0.01 wt % to about 10 wt %, about 0.01 wt % to about 7 wt %, about 0.01 wt % to about 5 wt %, about 0.01 wt % to about 4 wt %, about 0.01 wt % to about 3 wt %, about 0.01 wt % to about 2 wt %, about 0.01 wt % to about 1 wt %, about 0.01 wt % to about 0.5 wt %, about 0.01 wt % to about 0.1 wt %, about 0.05 wt % to about 20 wt %, about 0.05 wt % to about 15 wt %, about 0.05 wt % to about 10 wt %, about 0.05 wt % to about 7 wt %, about 0.05 wt % to about 5 wt %, about 0.05 wt % to about 4 wt %, about 0.05 wt % to about 3 wt %, about 0.05 wt % to about 2 wt %, about 0.05 wt % to about 1 wt %, about 0.05 wt % to about 0.5 wt %, about 0.05 wt % to about 0.1 wt %, about 0.06 wt % to about 0.4 wt %, about 0.07 wt % to about 0.3 wt %, or about 0.075 wt % to about 0.2 wt %.

### Ammonium Compound Included in Selective Etching Inhibitor

The selective etching inhibitor may include the ammonium compound.

The ammonium compound may serve to protect at least a portion of the metal-containing film through the electrostatic attraction. More specifically, since the ammonium compound has a smaller molecular size than the polymer having a nitrogen-containing repeating unit, the ammonium compound may effectively reach regions (e.g., regions between the polymers, etc.) of the metal-containing film that are not protected by the polymer, thereby serving to protect the metal-containing film more effectively. Furthermore, since the ammonium compound may be easily removed afterward, use of the ammonium compound may effectively perform a method of treating the metal-containing film.

The ammonium compound may include a cation and an anion.

In one or more embodiments, the ammonium compound may include an ammonium based cation represented by [N(X₁)(X₂)(X₃)(X₄)]⁺. Here, X₁ to X₄ may each independently be hydrogen or a C₁-C₂₀ alkyl group. For example, X₁ to X₄ may each independently be hydrogen or a C₁-C₁₀ alkyl group. In one or more embodiments, X₁ to X₄ may each independently be hydrogen.

In one or more embodiments, the ammonium compound may include a NH⁴⁺ cation.

In one or more embodiments, the ammonium compound may include an anion, wherein the anion may include F⁻, Cl⁻, Br⁻, I⁻, [OH]⁻, [(R₁₀) CO₂]⁻, [CO₃]²⁻, [NO₃]⁻, [SO₄]²⁻, [(R₁₀)SO₄]⁻, [(R₁₀)SO₃]⁻, [C₆H₇O₇]⁻, [C₆H₆O₇]²⁻, [C₆H₅O₇]³⁻, [PO₃]³⁻, [SO₃]²⁻, [C₂O₄]²⁻, [C₄H₄O₆]²⁻, [C₅H₈NO₄]⁻, [C₇H₅O₃]⁻, [BF₄]⁻, or any combination thereof.

Here, R₁₀ may be hydrogen, deuterium, *—OH, *—SH, *—NH₂, a C₁-C₂₀ alkyl group (e.g., a C₁-C₁₀ alkyl group), a C₂-C₂₀ alkenyl group (e.g., a C₂-C₁₀ alkenyl group), a C₁-C₂₀ alkoxy group (e.g., a C₁-C₁₀ alkoxy group), a C₆-C₂₀ aryl group (e.g., a phenyl group, a naphthyl group, etc.), a C₂-C₂₀ heteroaryl group (e.g., a pyridinyl group, etc.), or any combination thereof. In R₁₀, the C₁-C₂₀ alkyl group, the C₂-C₂₀ alkenyl group, the C₁-C₂₀ alkoxy group, the C₆-C₂₀ aryl group, and/or the C₂-C₂₀ heteroaryl group may each be unsubstituted or substituted with deuterium, *—F, *—Cl, *—Br, *—I, *—OH, *—SH, *—NH₂, *—C(—O)—OH, a C₁-C₂₀ alkyl group, a C₁-C₂₀ alkoxy group, or any combination thereof.

In one or more embodiments, the anion may include Cl⁻, [OH]⁻, [(R₁₀) CO₂]⁻, [NO₃]⁻, [SO₄]²⁻, or [(R₁₀)SO₃]⁻, wherein R₁₀ may be: hydrogen, deuterium, *—OH, *—SH, *—NH₂, a C₁-C₁₀ alkyl group (unsubstituted or substituted with deuterium, *—F, *—Cl, *—Br, *—I, *—OH, *—SH, *—NH₂, *—C(═O)—OH, a C₁-C₁₀ alkyl group, a C₁-C₁₀ alkoxy group, or any combination thereof) or any combination thereof.

In one or more embodiments, the anion may include F⁻, Cl⁻, Br⁻, I⁻, hydroxide, acetate, bicarbonate, benzoate, carbonate, formate, nitrate, sulfate, hydrogensulfate, carbamate, trifluoroacetate, sulfamate, trifluoromethanesulfonate, monohydrogencitrate, citrate, phosphate, sulfite, sulfobenzoate, oxalate, lactate, tartrate, dihydrogencitrate, glutamate, salicylate, bioxalate, octanoate, propionate, glycolate, tetrafluoroborate, gluconate, or any combination thereof.

In one or more embodiments, the ammonium compound may include ammonium fluoride, ammonium chloride, ammonium bromide, ammonium iodide, ammonium hydroxide, ammonium acetate, ammonium bicarbonate, ammonium benzoate, ammonium carbonate, ammonium formate, ammonium nitrate, ammonium sulfate, ammonium hydrogensulfate, ammonium carbamate, ammonium trifluoroacetate, ammonium sulfamate, ammonium trifluoromethanesulfonate, ammonium citrate dibasic, ammonium citrate tribasic, ammonium phosphate tribasic, ammonium sulfite, 2-sulfobenzoic acid ammonium salt, ammonium oxalate monohydrate, ammonium lactate, ammonium tartrate, ammonium dihydrogencitrate, L-glutamic acid monoammonium salt, ammonium salicylate, ammonium bioxalate monohydrate, ammonium octanoate, ammonium propionate, ammonium glycolate, ammonium tetrafluoroborate, ammonium gluconate, or any combination thereof.

The amount (weight) of the ammonium compound may be, for example (per 100 wt % of the composition) in a range of about 0.001 wt % to about 20 wt %, about 0.001 wt % to about 15 wt %, about 0.001 wt % to about 10 wt %, about 0.001 wt % to about 7 wt %, about 0.001 wt % to about 5 wt %, about 0.001 wt % to about 4 wt %, about 0.001 wt % to about 3 wt %, about 0.001 wt % to about 2 wt %, about 0.001 wt % to about 1 wt %, about 0.01 wt % to about 20 wt %, about 0.01 wt % to about 15 wt %, about 0.01 wt % to about 10 wt %, about 0.01 wt % to about 7 wt %, about 0.01 wt % to about 5 wt %, about 0.01 wt % to about 4 wt %, about 0.01 wt % to about 3 wt %, about 0.01 wt % to about 2 wt %, about 0.01 wt % to about 1 wt %, about 0.05 wt % to about 20 wt %, about 0.05 wt % to about 15 wt %, about 0.05 wt % to about 10 wt %, about 0.05 wt % to about 7 wt %, about 0.05 wt % to about 5 wt %, about 0.05 wt % to about 4 wt %, about 0.05 wt % to about 3 wt %, about 0.05 wt % to about 2 wt %, about 0.05 wt % to about 1 wt %, about 0.02 wt % to about 1.5 wt %, about 0.03 wt % to about 1.3 wt %, about 0.04 wt % to about 1.2 wt %, about 0.1 wt % to about 1.1 wt %, about 0.2 wt % to about 1 wt %, about 0.3 wt % to about 0.9 wt %, about 0.4 wt % to about 0.8 wt %, or about 0.5 wt % to about 0.7 wt %.

The weight ratio of the polymer having a nitrogen-containing repeating unit (based on the solids thereof) to the ammonium compound may be in a range of about 1:0.01 to about 1:50, about 1:0.1 to about 1:30, about 1:0.1 to about 1:15, about 1:0.2 to about 1:14, about 1:0.3 to about 1:13.5, about 1:0.4 to about 1:13, about 1:0.5 to about 1:12, about 1:0.5 to about 1:1, about 1:0.5 to about 1:0.8, about 1:4 to about 1:11, about 1:5 to about 1:10, or about 1:5 to about 1:7. When the weight ratio of the polymer having a nitrogen-containing repeating unit to the ammonium compound is within the above ranges above, the control of the etching rate for the metal-containing film may be effectively achieved.

The selective etching inhibitor may further include, in addition to the polymer having a nitrogen-containing repeating unit and the ammonium compound, an amine-containing compound that is different from the polymer having a nitrogen-containing repeating unit. By further including the amine-containing compound, the etching rate and etching selectivity ratio for the metal-containing film may be effectively controlled.

In one or more embodiments, the amine-containing compound may include alkylamine, alkanolamine, or any combination thereof.

In one or more embodiments, the amine-containing compound may include monoalkylamine (e.g., monobutylamine), monoalkanolamine (e.g., ethanolamine), or any combination thereof.

In one or more embodiments, the amine-containing compound may include a compound represented by Formula 5:

N(Q₅₁)(Q₅₂)(Q₅₃). Formula 5

In Formula 5, Q₅₁ to Q₅₃ may each independently be: hydrogen, deuterium, *—F, *—Cl, *—Br, *—I, *—OH, *—SH, *—C(═O)—H, *—C(═O)—OH, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), *—N(CH₃)₂, a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or any combination thereof. In formula 5, the C₁-C₃₀ alkyl group, the C₁-C₃₀ alkoxy group, the C₂-C₃₀ alkenyl group, the C₃-C₃₀ carbocyclic group, and/or the C₁-C₃₀ heterocyclic group may each be unsubstituted or substituted with deuterium, *—F, *—Cl, *—Br, *—I, *—OH, *—SH, *—C(═O)—H, *—C(═O)—OH, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), *—N(CH₃)₂, a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or any combination thereof, and at least one of Q₅₁ to Q₅₃ may not be hydrogen.

For example, Q₅₁ to Q₅₃ in Formula 5 may each independently be: hydrogen; or a C₁-C₃₀ alkyl group, a C₁-C₃₀ alkoxy group, a C₂-C₃₀ alkenyl group, a C₃-C₃₀ carbocyclic group, and/or a C₁-C₃₀ heterocyclic group, each unsubstituted or substituted with *—F, *—Cl, *—Br, *—I, *—OH, *—SH, *—C(═O)—H, *—C(═O)—OH, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), *—N(CH₃)₂, a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or any combination thereof, and at least one of Q₅₁ to Q₅₃ may not be hydrogen.

In one or more embodiments, in Formula 5, Q₅₁ and Q₅₂ may each be hydrogen, and Q₅₃ may be: a C₁-C₂₀ alkyl group; or a C₁-C₂₀ alkyl group substituted with *—F, *—OH, or any combination thereof.

When the selective etching inhibitor further includes the amine-containing compound, the weight ratio of the polymer having a nitrogen-containing repeating unit to the amine-containing compound may be in a range of about 1:0.01 to about 1:10.

The amount (weight) of the selective etching inhibitor may be, for example, per 100 wt % of the composition, in a range of about 0.001 wt % to about 20 wt %, about 0.001 wt % to about 15 wt %, about 0.001 wt % to about 10 wt %, about 0.001 wt % to about 7 wt %, about 0.001 wt % to about 5 wt %, about 0.001 wt % to about 4 wt %, about 0.001 wt % to about 3 wt %, about 0.001 wt % to about 2 wt %, about 0.001 wt % to about 1.5 wt %, about 0.01 wt % to about 20 wt %, about 0.01 wt % to about 15 wt %, about 0.01 wt % to about 10 wt %, about 0.01 wt % to about 7 wt %, about 0.01 wt % to about 5 wt %, about 0.01 wt % to about 4 wt %, about 0.01 wt % to about 3 wt %, about 0.01 wt % to about 2 wt %, about 0.01 wt % to about 1.5 wt %, about 0.1 wt % to about 20 wt %, about 0.1 wt % to about 15 wt %, about 0.1 wt % to about 10 wt %, about 0.1 wt % to about 7 wt %, about 0.1 wt % to about 5 wt %, about 0.1 wt % to about 4 wt %, about 0.1 wt % to about 3 wt %, about 0.1 wt % to about 2 wt %, or about 0.1 wt % to about 1.5 wt %. In this regard, the amount of the polymer having a nitrogen-containing repeating unit included in the selective etching inhibitor may be evaluated based on the solids.

In one or more embodiments, in the composition, the amount of the oxidizing agent may be, per 100 wt % of the composition, in a range of about 0.5 wt % to about 20 wt %, the amount of the acid may be, per 100 wt % of the composition, in a range of about 30 wt % to about 80 wt %, and the amount of the selective etching inhibitor may be, per 100 wt % of the composition, in a range of about 0.01 wt % to about 2 wt %.

The aforementioned composition may have a pH in a range of about 1.0 to about 8.0, about 1.0 to about 7.0, about 1.0 to about 6.0, about 1.0 to about 5.0, about 1.0 to about 4.0, about 1.0 to about 3.0, about 2.0 to about 8.0, about 2.0 to about 7.0, about 2.0 to about 6.0, about 2.0 to about 5.0, about 2.0 to about 4.0, about 2.0 to about 3.0, about 3.0 to about 8.0, about 3.0 to about 7.0, about 3.0 to about 6.0, about 3.0 to about 5.0, about 3.0 to about 4.0, about 4.0 to about 8.0, about 4.0 to about 7.0, about 4.0 to about 6.0, about 4.0 to about 5.0, about 5.0 to about 8.0, about 5.0 to about 7.0, or about 5.0 to about 6.0. When the pH of the composition is within the ranges above, the interaction between the selective etching inhibitor and metal atoms included in the metal-containing film may be more smoothly achieved.

In one or more embodiments, the composition may be used in a process of treating the metal-containing film, such as an etching, cleaning, or polishing process on the metal-containing film. The metal-containing film is the same as described herein.

In one or more embodiments, the composition may be used as a scavenger of an etching by-product, a scavenger of a post-etch process by-product, a scavenger of an ashing process by-product, a cleaning composition, a photoresist (PR) scavenger, an etching composition for packaging process, a cleaning agent for packaging process, a removing agent for adhesive substances of wafer, an etchant, a post-etch residue stripper, an ash residue cleaner, a PR residue stripper, a chemical-mechanical polishing (CMP) cleaner, a post-CMP cleaner, and/or the like.

### Method of Treating Metal-Containing Film and Method of Manufacturing Semiconductor Device

By using the aforementioned composition, the metal-containing film may be effectively treated.

Referring to the FIGURE, a method of treating the metal-containing film according to an embodiment may include: preparing a substrate provided with a metal-containing film (S100); and contacting the metal-containing film with the composition described herein (S110).

The metal-containing film is the same as described herein.

For example, a metal included in the metal-containing film may include Ti, In, Al, Co, La, Sc, Ga, W, Mo, Ru, Zn, Hf, Cu, or any combination thereof.

In one or more embodiments, the metal-containing film may include a metal, metal nitride, metal oxide, metal oxynitride, or any combination thereof.

In one or more embodiments, the metal-containing film may include TiN.

In one or more embodiments, the metal-containing film may include W.

In an embodiment, by the contacting of the metal-containing film with the composition, at least a portion of the metal-containing film may be etched, cleaned, or polished.

Since the composition includes the selective etching inhibitor that includes the ammonium compound and the polymer having a nitrogen-containing repeating unit at the same time, the etching rate for various metal-containing films may be easily controlled.

Meanwhile, referring to the FIGURE, a method manufacturing a semiconductor device according to an embodiment may include: preparing a substrate provided with a metal-containing film (S100); contacting the metal-containing film with the composition (S110); and manufacturing a semiconductor device by performing a subsequent process (S120). For example, in at least one example, the composition may be deposited, during operation S110 to partially and/or completely cover the metal-containing film such that during operation S120, the areas of the metal-containing film covered by the composition are cleaned. For example, without being limited to a specific mechanism, in at least some embodiments, the oxidizing agent and the acid may act together as a cleaning composition selected for removing organic materials, and meanwhile, the selective etching inhibitor that includes the ammonium compound and the polymer having a nitrogen-containing repeating unit may control (e.g., suppress) the etching rate for the metal-containing films, and thus the composition may be used to remove an organic film (or residue) from the substrate without damaging the metal-containing film. In at least some embodiments, the organic residue may be, for example, the residue of a photoresist and/or the like. In this case, the subsequent process may include, e.g., polishing, deposition, etc. Additionally, in at least some embodiments, the composition may be applied in a wet etch operation, wherein, e.g., the composition is used to remove a nonreacted portion of a resist. In this case, the subsequent process may include, e.g., polishing, etching, etc.

### Examples 1 to 5 and Comparative Examples A and B

Compositions of Examples 1 to 5 and Comparative Examples A and B were each prepared by mixing 4 wt % of hydrogen peroxide as an oxidizing agent, 70 wt % of phosphoric acid as an acid, and a selective etching inhibitor listed in Tables 1 and 2. Here, the weight average molecular weight of Polymer P1 was 1,600 gram per mole (g/mol), and the remaining of each composition was water (deionized water). Comparative Examples A and B included no polymer and no ammonium compound, and ammonium compound but no polymer, respectively.

### Evaluation Example 1

The composition of Example 1 was added to a beaker and heated to a temperature of 70° C. Then, a tungsten (W) film specimen having a size of 1 centimeter (cm)×1 cm was immersed in the beaker for 5 minutes. The thickness of the W film was measured by using an ellipsometer (M-2000, J. A. Woolam), a four-point resistivity meter, and X-ray fluorescence (XRF), to evaluate the etching rate (angstrom per minute (Å/min)) for the W film, and the results are shown in Table 1.

The same test was repeated by using the compositions of Examples 2 to 4 and Comparative Examples A and B, and the results are summarized in Table 1.

TABLE 1

| | | | | | Etching |
|---|---|---|---|---|---|
| | Selective etching inhibitor | | | | rate |
| | | Solids | | Amount of | for |
| | | amount | | ammonium | tungsten |
| | Poly- | of polymer | Ammonium | compound | film |
| | mer | (wt %) | compound | (wt %) | (Å/min) |
| Example 1 | P1 | 0.1 | NH₄OH | 0.5 | 2.7 |
| Example 2 | P1 | 0.1 | NH₄(SO₃CF₃) | 0.05 | 1.5 |
| Example 3 | P1 | 0.075 | NH₄OH | 0.5 | 2.8 |
| Example 4 | P1 | 0.1 | NH₄OH | 1 | 2.2 |
| Comparative | — | — | — | — | 33.2 |
| Example | | | | | |
| A | | | | | |
| Comparative | — | — | NH₄OH | 0.5 | 27.2 |
| Example | | | | | |
| B | | | | | |

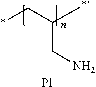

Referring to Table 1, it was confirmed that the compositions of Examples 1 to 4 had excellent performance of inhibiting etching of the W film compared to the compositions of Comparative Examples A and B.

### Evaluation Example 2

The etching rate (Å/min) for a titanium nitride (TiN) film was evaluated by using each of the compositions of Examples 3 and 5 and Comparative Examples A and B according to the same method as Evaluation Example 1, except that a TiN film specimen was used instead of the W film specimen, and the results are summarized in Table 2.

TABLE 2

| | | | | | Etching |
|---|---|---|---|---|---|
| | Selective etching inhibitor | | | | rate for |
| | | Solids | | Amount of | titanium |
| | | amount | | ammonium | nitride |
| | Poly- | of polymer | Ammonium | compound | film |
| | mer | (wt %) | compound | (wt %) | (Å/min) |
| Example 3 | P1 | 0.075 | NH₄OH | 0.5 | 31 |
| Example 5 | P1 | 0.075 | NH₄OH | 1 | 22 |
| Comparative | — | — | — | — | 54.9 |
| Example | | | | | |
| A | | | | | |
| Comparative | — | — | NH₄OH | 0.5 | 48.7 |
| Example | | | | | |
| B | | | | | |

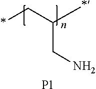

Referring to Table 2, it was confirmed that the compositions of Examples 3 and 5 had excellent performance of inhibiting etching of the TiN film compared to the compositions of Comparative Examples A and B.

According to the one or more embodiments, a composition enables to easily control the etching rate for various metal-containing films, and may be effectively used in various treatment processes for a metal-containing film, such as etching, cleaning, polishing, etc. In this regard, when a metal-containing film is treated by using the composition, a high-quality semiconductor device may be manufactured.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A composition comprising:
an oxidizing agent;
an acid; and
a selective etching inhibitor,
wherein the selective etching inhibitor comprises an ammonium compound and a polymer having a nitrogen-containing repeating unit.

2. The composition of claim 1, wherein the oxidizing agent comprises hydrogen peroxide.

3. The composition of claim 1, wherein the acid comprises at least one of phosphoric acid, hydrochloric acid, and chloric acid.

4. The composition of claim 1, wherein the nitrogen-containing repeating unit comprises at least one of a repeating unit represented by Formula 1-1, a repeating unit represented by Formula 1-2, a repeating unit represented by Formula 1-3, a repeating unit represented by Formula 1-4, or a combination thereof: 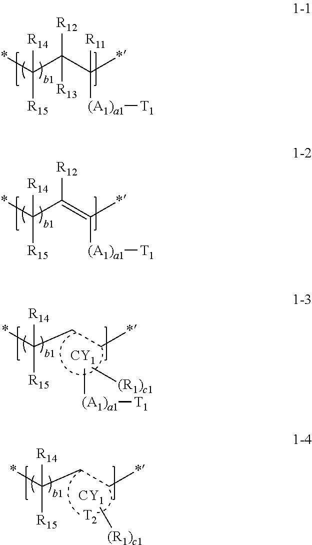
wherein A₁ in Formulae 1-1 to 1-3 is at least one of *—C(R₁₆)(R₁₇)—*′, *—N(R₁₆)—**, *—C(═O)—*′, *—O—*′, or *—S—*′,
a1 in Formulae 1-1 to 1-3 is an integer from 0 to 20,
b1 in Formulae 1-1 to 1-4 is an integer from 0 to 10,
T₁ in Formulae 1-1 to 1-3 is *—N(Z₁₁)(Z₁₂), *—[N(Z₁₁)(Z₁₂)(Z₁₃)]⁺[Z₁₄]⁻, a group represented by Formula AN, or a group represented by Formula BN, 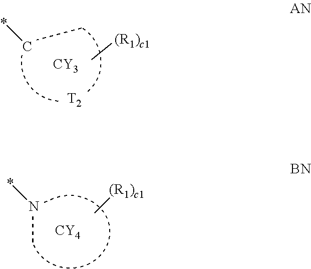
ring CY₁ to ring CY₄ in Formulae 1-3, 1-4, AN, and BN are each independently a C₂-C₁₀ cyclic group,
c1 in Formulae 1-3, 1-4, AN, and BN is an integer from 0 to 10,
T₂ in Formulae 1-4 and AN is *—N(Z₁₁)—*′ or *—[N(Z₁₁)(Z₁₂)]⁺[Z₁₄]⁻—*′, and
R₁, R₁₁, R₁₂, R₁₃, R₁₄, R₁₅, R₁₆, R₁₇, Z₁₁, Z₁₂, and Z₁₃ are each independently at least one of
hydrogen, deuterium, *—F, *—Cl, *—Br, *—I, *—OH, *—SH, *—C(═O)-Q₁, *—NH—C(═O)-Q₁, *—C(═O)—O-Q₁, *—SO₂-Q₁, *—P(═O)-(Q₁)(Q₂), *—N(Q₁)(Q₂), *—[N(Q₁)(Q₂)(Q₃)]⁺[Q₄]⁻, or *—(O—CH₂CH₂)ₙ₁—OH, or
a C₁-C₃₀ alkyl group, a C₁-C₃₀ alkoxy group, a C₂-C₃₀ alkenyl group, a C₃-C₃₀ carbocyclic group, or a C₁-C₃₀ heterocyclic group, each unsubstituted or substituted with deuterium, *—F, *—Cl, *—Br, *—I, *—OH, *—SH, *—C(—O)-Q₁₁, *—NH—C(═O)-Q₁₁, *—C(═O)—O-Q₁₁, *—SO₂-Q₁₁, *—P(═O)-(Q₁₁)(Q₁₂), *—N(Q₁₁)(Q₁₂), *—[N(Q₁₁)(Q₁₂)(Q₁₃)]⁺[Q₁₄]⁻, *—(O—CH₂CH₂)ₙ₂—OH, a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or a combination thereof,
n1 and n2 are each independently an integer from 1 to 20,
two or more of R₁, R₁₁, R₁₂, R₁₃, R₁₄, R₁₅, R₁₆, R₁₇, Z₁₁, Z₁₂, and Z₁₃ are optionally bonded together to form a cyclic group having 2 to 10 carbon atoms,
Q₁ to Q₃ and Q₁₁ to Q₁₃ are each independently
hydrogen, deuterium, *—F, *—Cl, *—Br, *—I, *—OH, *—SH, *—C(═O)—H, *—C(—O)—OH, *—C(═O)—NH₂, *—C(═O)—NH(CH₃), *—C(═O)—N(CH₃)₂, *—NH—C(—O)—NH₂, *—NH—C(═O)—NH(CH₃), *—NH—C(═O)—N(CH₃)₂, *—NH₂, *—NH(CH₃), or *—N(CH₃)₂, or
a C₁-C₃₀ alkyl group, a C₁-C₃₀ alkoxy group, a C₂-C₃₀ alkenyl group, a C₃-C₃₀ carbocyclic group, or a C₁-C₃₀ heterocyclic group, each unsubstituted or substituted with deuterium, *—F, *—Cl, *—Br, *—I, *—OH, *—SH, *—C(═O)—H, *—C(═O)—OH, *—C(—O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), *—N(CH₃)₂, a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, or a combination thereof,
[Z₁₄]⁻, [Q₄]⁻, and [Q₁₄]⁻ are each an anion, and
* and *′ each indicate a binding site to a neighboring atom.

5. The composition of claim 4, wherein CY₁ in Formula 1-3 is a cyclopropane group, a cyclobutane group, a cyclopentane group, a cyclohexane group, a cycloheptane group, a cyclooctane group, an oxirane group, an oxetane group, a tetrahydrofuran group, or a tetrahydropyran group.

6. The composition of claim 4, wherein ring CY₂ in Formula 1-4 is a saturated cyclic group having 4, 5, 6, or 7 carbon atoms.

7. The composition of claim 4, wherein in Formula AN,
i) T₂ is *—N(Z₁₁)—*′, and ring CY₃ is a pyrrole group, an imidazole group, a pyrazole group, an aziridine group, an azetidine group, a pyrrolidine group, or a piperidine group, or
ii) T₂ is *—[N(Z₁₁)(Z₁₂)]⁺[Z₁₄]⁻—*′, and ring CY₃ is a saturated cyclic group having 4, 5, 6, or 7 carbon atoms.

8. The composition of claim 4, wherein ring CY₄ in Formula BN is a pyrrole group, an imidazole group, a pyrazole group, an aziridine group, an azetidine group, a pyrrolidine group, or a piperidine group.

9. The composition of claim 1, wherein the polymer having the nitrogen-containing repeating unit is a homopolymer.

10. The composition of claim 1, wherein the polymer having the nitrogen-containing repeating unit is
a copolymer having a combination of two or more nitrogen-containing repeating units that are different each other, as the nitrogen-containing repeating unit, or
a copolymer further comprising at least one additional repeating unit that is different from the nitrogen-containing repeating unit, in addition to the nitrogen-containing repeating unit.

11. The composition of claim 1, wherein the ammonium compound comprises a cation represented by [N(X₁)(X₂)(X₃)(X₄)]⁺, wherein X₁ to X₄ are each independently hydrogen or a C₁-C₂₀ alkyl group.

12. The composition of claim 1, wherein
the ammonium compound comprises an anion comprising at least one of F⁻, Cl⁻, Br⁻, I⁻, [OH]⁻, [(R₁₀) CO₂]⁻, [CO₃]²⁻, [NO₃]⁻, [SO₄]²⁻, [(R₁₀)SO₄]⁻, [(R₁₀)SO₃]⁻, [C₆H₇O₇]⁻, [C₆H₆O₇]²⁻, [C₆H₅O₇]³⁻, [PO₃]³⁻, [SO₃]²⁻, [C₂O₄]²⁻, [C₄H₄O₆]²⁻, [C₅H₈NO₄]⁻, [C₇H₅O₃]⁻, [BF₄]⁻, or a combination thereof,
wherein R₁₀ is one of
hydrogen, deuterium, *—OH, *—SH, or *—NH₂, or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with deuterium, *—F, *—Cl, *—Br, *—I, *—OH, *—SH, *—NH₂, *—C(—O)—OH, a C₁-C₂₀ alkyl group, a C₁-C₂₀ alkoxy group, or combination thereof.

13. The composition of claim 1, wherein the ammonium compound comprises ammonium fluoride, ammonium chloride, ammonium hydroxide, ammonium acetate, ammonium bicarbonate, ammonium benzoate, ammonium carbonate, ammonium formate, ammonium nitrate, ammonium sulfate, ammonium hydrogensulfate, ammonium carbamate, ammonium trifluoroacetate, ammonium sulfamate, ammonium trifluoromethanesulfonate, ammonium citrate dibasic, ammonium citrate tribasic, ammonium phosphate tribasic, ammonium sulfite, 2-sulfobenzoic acid ammonium salt, ammonium oxalate monohydrate, ammonium lactate, ammonium tartrate, ammonium dihydrogencitrate, L-glutamic acid monoammonium salt, ammonium salicylate, ammonium bioxalate monohydrate, ammonium octanoate, ammonium propionate, ammonium glycolate, ammonium tetrafluoroborate, ammonium gluconate, or any combination thereof.

14. The composition of claim 1, wherein an amount of the selective etching inhibitor is in a range of about 0.001 wt % to about 20 wt %, per 100 wt % of the composition.

15. The composition of claim 1, wherein
an amount of the oxidizing agent is in a range of about 0.5 wt % to about 20 wt %, per 100 wt % of the composition,
an amount of the acid is in a range of about 30 wt % to about 80 wt %, per 100 wt % of the composition, and
an amount of the selective etching inhibitor is in a range of about 0.01 wt % to about 2 wt %, per 100 wt % of the composition.

16. A method of treating a metal-containing film, the method comprising:
preparing a substrate provided with a metal-containing film; and
contacting the metal-containing film with the composition of claim 1.

17. The method of claim 16, wherein a metal included in the metal-containing film comprises titanium (Ti), indium (In), aluminum (Al), cobalt (Co), lanthanum (La), scandium (Sc), gallium (Ga), tungsten (W), molybdenum (Mo), ruthenium (Ru), zinc (Zn), hafnium (Hf), copper (Cu), or a combination thereof.

18. The method of claim 16, wherein the metal-containing film comprises a metal, metal nitride, metal oxide, metal oxynitride, or a combination thereof.

19. The method of claim 16, wherein, by the contacting of the metal-containing film with the composition, at least a portion of the metal-containing film is etched, cleaned, or polished.

20. A method of manufacturing a semiconductor device, the method comprising:
preparing a substrate provided with a metal-containing film;
contacting the metal-containing film with the composition of claim 1; and
preparing the semiconductor device by performing at least one subsequent manufacturing process.
